(19) United States
(12) Patent Application Publication
(10) Pub. No.: US 2025/0228113 A1
(43) Pub. Date: Jul. 10, 2025

(54) DISPLAY DEVICE AND METHOD OF MANUFACTURING THE SAME

(71) Applicant: Samsung Display Co., LTD., Yongin-si (KR)

(72) Inventors: Mi Yeon CHO, Yongin-si (KR); Dae Ho SONG, Yongin-si (KR); Eun Ho SONG, Yongin-si (KR); Seok Hyun LIM, Yongin-si (KR)

(21) Appl. No.: 18/987,221

(22) Filed: Dec. 19, 2024

(30) Foreign Application Priority Data
Jan. 9, 2024 (KR) 10-2024-0003571

(51) Int. Cl. H10K 59/80; H10K 59/12; H10K 59/122

(52) U.S. Cl. CPC H10K 59/8791; H10K 59/1201; H10K 59/122; H10K 59/80515

(57) ABSTRACT

A display device includes: a substrate; a pixel circuit layer on the substrate; anode electrodes on the pixel circuit layer; a pixel defining layer on a portion of the anode electrodes and the pixel circuit layer, and having a recessed shape in a direction of the substrate between the anode electrodes, wherein the recessed shape is arranged along a circumference of each of the anode electrodes; a light emitting structure on the anode electrodes and the pixel defining layer and including a plurality of light generation layers; a cathode electrode on the light emitting structure; and a reflective layer overlapping the recessed shape and located between the light emitting structure and the pixel circuit layer.

### CROSS-REFERENCE TO RELATED APPLICATION

The present application claims priority to and the benefit of Korean Patent Application No. 10-2024-0003571, filed on Jan. 9, 2024, in the Korean Intellectual Property Office, the entire disclosure of which is incorporated herein by reference.

### BACKGROUND

### 1. Field

Aspects of some embodiments of the present disclosure relate to a display device and a method of manufacturing the same.

### 2. Description of the Related Art

As consumer interest in information displays has recently increased, research and development on display devices is continuously being conducted.

In particular, because an organic light emitting diode (OLED) is an active light emitting display element that has an advantage of not only having a relatively wide viewing angle and excellent contrast, but also being able to be driven at a relatively low voltage, being lightweight and thin, and having a relatively fast response speed, is attracting attention as a next-generation display element.

The above information disclosed in this Background section is only for enhancement of understanding of the background and therefore the information discussed in this Background section does not necessarily constitute prior art.

### SUMMARY

Aspects of some embodiments of the present disclosure include a display device with relatively improved reliability. For example, the display device may relatively improve a lateral leakage phenomenon occurring between adjacent sub- pixels by forming or arranging a reflective layer between the adjacent sub-pixels in a pixel.

Aspects of some embodiments of the present disclosure include a method of manufacturing a display device with relatively improved reliability.

According to some embodiments of the present disclosure, a display device includes a substrate, a pixel circuit layer on the substrate, anode electrodes on the pixel circuit layer, a pixel defining layer on a portion of the anode electrodes and the pixel circuit layer, and having a recessed shape, which is arranged along a circumference of each of the anode electrodes, in a direction of the substrate between the anode electrodes, a light emitting structure on the anode electrodes and the pixel defining layer and including a plurality of light generation layers, a cathode electrode on the light emitting structure, and a reflective layer overlapping the recessed shape and between the light emitting structure and the pixel circuit layer.

According to some embodiments, the reflective layer may be arranged along the circumference of each of the anode electrodes.

According to some embodiments, the reflective layer may include the same material as the anode electrodes.

According to some embodiments, a sub-trench further recessed from the recessed shape may be between one of the anode electrodes and the reflective layer, and the sub-trench may be arranged along a circumference of the one of the anode electrodes.

According to some embodiments, a first sub-trench further recessed from the recessed shape between one of the anode electrodes and the reflective layer, and a second sub-trench further recessed from the recessed shape between another of the anode electrodes and the reflective layer may be arranged.

According to some embodiments, the light emitting structure may include at least two light emitting units sequentially stacked and at least one charge generation layer between the light emitting units, each of the at least two light emitting units may include a light emitting layer, and the at least one charge generation layer may be disconnected in an area overlapping the recessed shape.

According to some embodiments, the reflective layer may have a lower surface adjacent to the substrate and an upper surface opposite to the lower surface, and the upper surface of the reflective layer may have a recessed shape in a direction facing the substrate.

According to some embodiments, the lower surface of the reflective layer may have a recessed shape in the direction facing the substrate.

According to some embodiments, the reflective layer may include a base surface parallel to the substrate and inclined surfaces extending from the base surface, and each of the inclined surfaces may be inclined at a predetermined angle with respect to the base surface.

According to some embodiments, each of the inclined surfaces may have an angle of 45 degrees or more with respect to the base surface.

According to some embodiments, the reflective layer may have a first width, and the base surface has a second width narrower than the first width.

According to some embodiments, the anode electrode may have a quadrangular shape or a hexagonal shape in a plan view.

According to some embodiments of the present disclosure, in a method of manufacturing a display device, the method includes forming anode electrodes on a substrate, forming a pixel defining layer, which forms a recessed shape in a direction of the substrate between the anode electrodes along a circumference of each of the anode electrodes, on a portion of the anode electrodes and the pixel circuit layer, forming a reflective layer overlapping the recessed shape, forming a light emitting structure including a plurality of light generation layers on the anode electrodes and the pixel defining layer, and forming a cathode electrode on the light emitting structure, and the reflective layer is between the light emitting structure and the pixel circuit layer.

According to some embodiments, the method may further include positioning a mask having an opening overlapping the reflective layer on the cathode electrode, and irradiating ultraviolet rays through the opening.

According to some embodiments, the reflective layer may be arranged along the circumference of each of the anode electrodes.

According to some embodiments, the reflection layer may include the same material as the anode electrodes.

According to some embodiments, the reflective layer may have a lower surface adjacent to the substrate and an upper surface opposite to the lower surface, and the upper surface of the reflective layer may have a recessed shape in a direction facing the substrate.

According to some embodiments, the reflective layer may include a base surface parallel to the substrate and inclined surfaces extending from the base surface, and each of the inclined surfaces may be inclined at a predetermined angle with respect to the base surface.

### BRIEF DESCRIPTION OF THE DRAWINGS

The above and other characteristics of embodiments according to the present disclosure will become more apparent by describing in further detail aspects of some embodiments thereof with reference to the accompanying drawings, in which:

FIG. 1 is a block diagram illustrating aspects of a display device of the disclosure, according to some embodiments;

FIG. 2 is a block diagram illustrating aspects of a sub-pixel of FIG. 1, according to some embodiments;

FIG. 3 is a plan view illustrating further details of the display panel of FIG. 1, according to some embodiments;

FIG. 4 is an exploded perspective view illustrating a portion of the display panel of FIG. 3;

FIG. 5 is a plan view illustrating further details of a pixel of FIG. 4 according to some embodiments;

FIG. 6 is a cross-sectional view taken along a line I˜I′ of FIG. 5;

FIG. 7 is a cross-sectional view illustrating aspects of a light emitting structure included in any of first to third light emitting elements of FIG. 6, according to some embodiments;

FIG. 8 is a cross-sectional view illustrating further details of the light emitting structure included in any of the first to third light emitting elements of FIG. 6, according to some embodiments;

FIG. 9 is an enlarged view illustrating a portion A of FIG. 6;

FIG. 10 is an enlarged view illustrating aspects of the reflective layers of FIG. 6, according to some embodiments;

FIGS. 11 and 12 are plan views illustrating further details of the pixel of FIG. 4, according to some embodiments;

FIG. 13 is a plan view illustrating further details of the pixel of FIG. 4, according to some embodiments;

FIG. 14 is a cross-sectional view taken along a line II˜ II′ of FIG. 13;

FIG. 15 is a flowchart illustrating aspects of a method of manufacturing a display device, according to some embodiments; and

FIGS. 16 to 19 are cross-sectional views schematically illustrating a method of manufacturing a display device, according to some embodiments.

### DETAILED DESCRIPTION

Hereinafter, aspects of some embodiments of the present disclosure are described in more detail with reference to the accompanying drawings. It should be noted that in the following description, only portions necessary for understanding an operation according to the disclosure are described, and descriptions of other portions are omitted in order not to obscure the subject matter of the disclosure. In addition, the disclosure may be embodied in other forms without being limited to the embodiment described herein. However, the embodiments described herein are provided to describe in more detail enough to implement the technical spirit of the disclosure to those skilled in the art to which the disclosure belongs.

Throughout the specification, in a case where a portion is “connected” to another portion, the case includes not only a case where the portion is “directly connected” but also a case where the portion is “indirectly connected” with another element interposed therebetween. Terms used herein are for describing specific embodiments and are not intended to limit the disclosure. Throughout the specification, in a case where a certain portion “includes”, the case means that the portion may further include another component without excluding another component unless otherwise stated. “At least any one of X, Y, and Z” and “at least any one selected from a group consisting of X, Y, and Z” may be interpreted as one X, one Y, one Z, or any combination of two or more of X, Y, and Z (for example, XYZ, XYY, YZ, and ZZ). Here, “and/or” includes all combinations of one or more of corresponding configurations.

Here, terms such as first and second may be used to describe various components, but these components are not limited to these terms. These terms are used to distinguish one component from another component. Therefore, a first component may refer to a second component within a range without departing from the scope disclosed herein.

Spatially relative terms such as “under”, “on”, and the like may be used for descriptive purposes, thereby describing a relationship between one element or feature and another element(s) or feature(s) as shown in the drawings. Spatially relative terms are intended to include other directions in use, in operation, and/or in manufacturing, in addition to the direction depicted in the drawings. For example, when a device shown in the drawing is turned upside down, elements depicted as being positioned “under” other elements or features are positioned in a direction “on” the other elements or features. Therefore, in the present disclosure, the term “under” may include both directions of on and under. In addition, the device may face in other directions (for example, rotated 90 degrees or in other directions) and thus the spatially relative terms used herein are interpreted according thereto.

Various embodiments are described with reference to drawings schematically illustrating ideal embodiments. Accordingly, it will be expected that shapes may vary, for example, according to tolerances and/or manufacturing techniques. Therefore, the embodiments disclosed herein cannot be construed as being limited to shown specific shapes, and should be interpreted as including, for example, changes in shapes that occur as a result of manufacturing. As described above, the shapes shown in the drawings may not show actual shapes of areas of a device, and the present embodiments are not limited thereto.

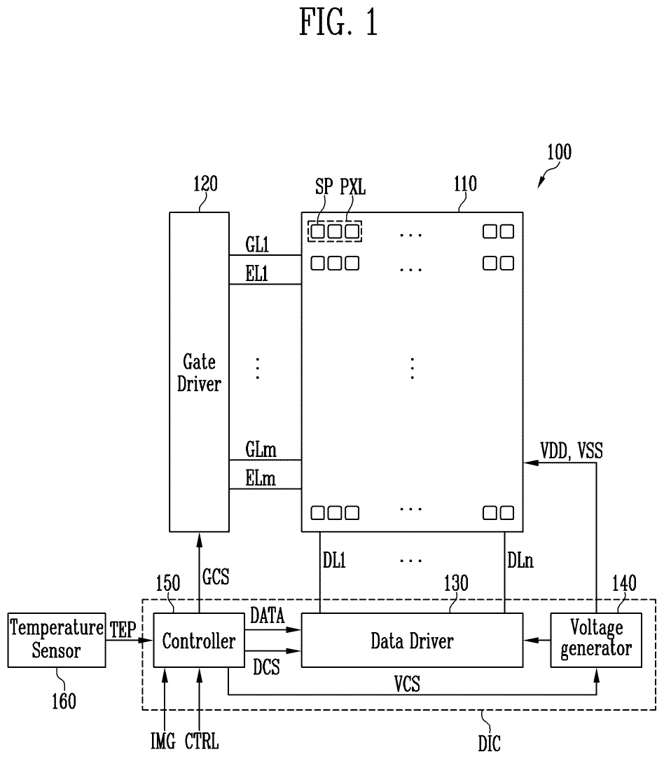

FIG. 1 is a diagram illustrating aspects of a display device, according to some embodiments.

Referring to FIG. 1, the display device 100 may include a display panel 110, a gate driver 120, a data driver 130, a voltage generator 140, and a controller 150.

The display panel 110 may include sub-pixels SP. The sub-pixels SP may be connected to the gate driver 120 through first to m-th gate lines GL1 to GLm. The sub-pixels SP may be connected to the data driver 130 through first to n-th data lines DL1 to DLn.

Each of the sub-pixels SP may include at least one light emitting element configured to generate light. Accordingly, each of the sub-pixels SP may generate light of a specific color such as red, green, blue, cyan, magenta, or yellow. Two or more sub-pixels among the sub-pixels SP may configure one pixel PXL. For example, as shown in FIG. 1, three sub-pixels may configure one pixel PXL.

The gate driver 120 may be connected to the sub-pixels SP arranged in a row direction through the first to m-th gate lines GL1 to GLm. The gate driver 120 may output gate signals to the first to m-th gate lines GL1 to GLm in response to a gate control signal GCS. According to some embodiments, the gate control signal GCS may include a start signal indicating a start of each frame, a horizontal synchronization signal for outputting the gate signals in synchronization with a timing at which data signals are applied, and the like.

According to some embodiments, first to m-th emission control lines EL1 to ELm connected to the sub-pixels SP of the row direction may be further provided. In this case, the gate driver 120 may include an emission control driver configured to control the first to m-th emission control lines EL1 to ELm, and the emission control driver may operate under control of the controller 150.

The gate driver 120 may be located on one side of the display panel 110. However, embodiments according to the present disclosure are not limited thereto. For example, the gate driver 120 may be divided into two or more physically and/or logically divided drivers, and such drivers may be located on one side of the display panel 110 and another side of the display panel 110 opposite the one side. As described above, the gate driver 120 may be arranged around the display panel 110 in various shapes according to embodiments.

The data driver 130 may be connected to the sub-pixels SP arranged in a column direction through the first to n-th data lines DL1 to DLn. The data driver 130 may receive image data DATA and a data control signal DCS from the controller 150.

The data driver 130 may operate in response to the data control signal DCS. According to some embodiments, the data control signal DCS may include a source start pulse, a source shift clock, a source output enable signal, and the like.

The data driver 130 may apply data signals having grayscale voltages corresponding to the image data DATA to the first to n-th data lines DL1 to DLn using voltages from the voltage generator 140. When the gate signal is applied to each of the first to m-th gate lines GL1 to GLm, the data signals corresponding to the image data DATA may be applied to the data lines DL1 to DLm. Accordingly, the corresponding sub-pixels SP may generate light corresponding to the data signals. Accordingly, images may be displayed on the display panel 110.

According to some embodiments, the gate driver 120 and the data driver 130 may include complementary metal-oxide semiconductor (CMOS) circuit elements.

The voltage generator 140 may operate in response to a voltage control signal VCS from the controller 150. The voltage generator 140 may be configured to generate a plurality of voltages and provide the generated voltages to components of the display device 100. For example, the voltage generator 140 may be configured to generate the plurality of voltages by receiving an input voltage from an outside of the display device 100, adjusting the received voltage, and regulating the adjusted voltage.

The voltage generator 140 may generate a first power voltage VDD and a second power voltage VSS, and the generated first and second power voltages VDD and VSS may be provided to the sub-pixels SP. The first power voltage VDD may have a relatively high voltage level, and the second power voltage VSS may have a voltage level lower than that of the first power voltage VDD. According to some embodiments, the first power voltage VDD or the second power voltage VSS may be provided by an external device of the display device 100.

In addition, the voltage generator 140 may generate various voltages. For example, the voltage generator 140 may generate an initialization voltage applied to the sub-pixels SP. For example, during a sensing operation for sensing electrical characteristics of transistors and/or light emitting elements of the sub-pixels SP, a reference voltage (e.g., a set or predetermined reference voltage) may be applied to the first to n-th data lines DL1 to DLn, and the voltage generator 140 may generate such a reference voltage.

The controller 150 may control overall operations of the display device 100. The controller 150 may receive input image data IMG and a control signal CTRL for controlling display of the input image data IMG from the outside. The controller 150 may provide the gate control signal GCS, the data control signal DCS, and the voltage control signal VCS in response to the control signal CTRL.

The controller 150 may convert the input image data IMG so that the input image data IMG is suitable for the display device 100 or the display panel 110 and output the image data DATA. According to some embodiments, the controller 150 may output the image data DATA by aligning the input image data IMG so that the input image data IMG is suitable for the sub-pixels SP of a row unit.

Two or more components of the data driver 130, the voltage generator 140, and the controller 150 may be mounted on one integrated circuit. As shown in FIG. 1, the data driver 130, the voltage generator 140, and the controller 150 may be included in a driver integrated circuit DIC. In this case, the data driver 130, the voltage generator 140, and the controller 150 may be functionally divided components in one driver integrated circuit DIC. According to some embodiments, at least one of the data driver 130, the voltage generator 140, or the controller 150 may be provided as a component distinguished from the driver integrated circuit DIC.

The display device 100 may include at least one temperature sensor 160. The temperature sensor 160 may be configured to sense a temperature around the temperature sensor 160 and generate temperature data TEP indicating the sensed temperature. According to some embodiments, the temperature sensor 160 may be located adjacent to the display panel 110 and/or the driver integrated circuit DIC.

The controller 150 may control various operations of the display device 100 in response to the temperature data TEP. According to some embodiments, the controller 150 may adjust a luminance of the image output from the display panel 110 in response to the temperature data TEP. For example, the controller 150 may control the data signals and the first and second power voltages VDD and VSS by controlling components such as the data driver 130 and/or the voltage generator 140.

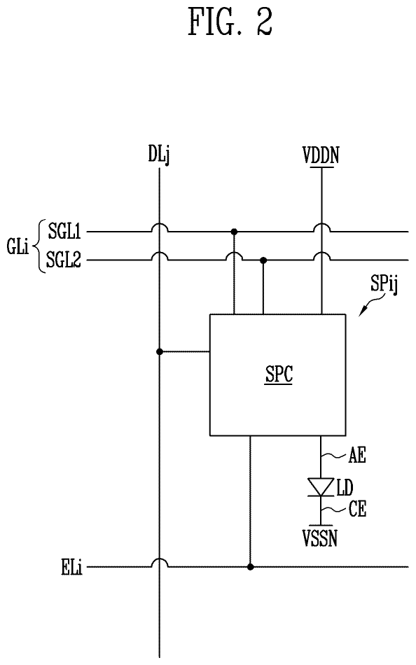

FIG. 2 is a block diagram illustrating an example of any one of the sub-pixels of FIG. 1. In FIG. 2, among the sub-pixels SP of FIG. 1, a sub-pixel SPij arranged in an i-th row (I is an integer greater than or equal to 1 and less than or equal to m) and a j-th column (j is an integer greater than or equal to 1 and less than or equal to n) is shown as an example.

Referring to FIG. 2, the sub-pixel SPij may include a sub-pixel circuit SPC and a light emitting element LD.

The light emitting element LD may be connected between a first power voltage node VDDN and a second power voltage node VSSN. At this time, the first power voltage node VDDN may be a node that transfers the first power voltage VDD of FIG. 1, and the second power voltage node VSSN may be a node that transfers the second power voltage VSS of FIG. 1.

An anode electrode AE of the light emitting element LD may be connected to the first power voltage node VDDN through the sub-pixel circuit SPC, and a cathode electrode CE of the light emitting element LD may be connected to the second power voltage node VSSN. For example, the anode electrode AE of the light emitting element LD may be connected to the first power voltage node VDDN through one or more transistors included in the sub-pixel circuit SPC.

The sub-pixel circuit SPC may be connected to an i-th gate line GLi among the first to m-th gate lines GL1 to GLm of FIG. 1, an i-th emission control line ELi among the first to m-th emission control lines EL1 to ELm of FIG. 1, and a j-th data line DLj among the first to n-th data lines DL1 to DLn of FIG. 1. The sub-pixel circuit SPC may be configured to control the light emitting element LD according to signals received through such signal lines.

The sub-pixel circuit SPC may operate in response to a gate signal received through the i-th gate line GLi. The i-th gate line GLi may include one or more sub-gate lines. According to some embodiments, as shown in FIG. 2, the i-th gate line GLi may include first and second sub-gate lines SGL1 and SGL2. The sub-pixel circuit SPC may operate in response to gate signals received through the first and second sub-gate lines SGL1 and SGL2. As described above, when the i-th gate line GLi includes two or more sub-gate lines, the sub-pixel circuit SPC may operate in response to gate signals received through the corresponding sub-gate lines.

The sub-pixel circuit SPC may operate in response to an emission control signal received through the i-th emission control line ELi. According to some embodiments, the i-th emission control line ELi may include one or more sub-emission control lines. When the i-th emission control line ELi includes two or more sub-emission control lines, the sub-pixel circuit SPC may operate in response to emission control signals received through the corresponding sub-emission control lines.

The sub-pixel circuit SPC may receive a data signal through the j-th data line DLj. The sub-pixel circuit SPC may store a voltage corresponding to the data signal in response to at least one of the gate signals received through the first or second sub-gate lines SGL1 or SGL2. The sub-pixel circuit SPC may adjust a current flowing from the first power voltage node VDDN to the second power voltage node VSSN through the light emitting element LD according to the stored voltage, in response the emission control signal received through the i-th emission control line ELi. Accordingly, the light emitting element LD may generate light of a luminance corresponding to the data signal.

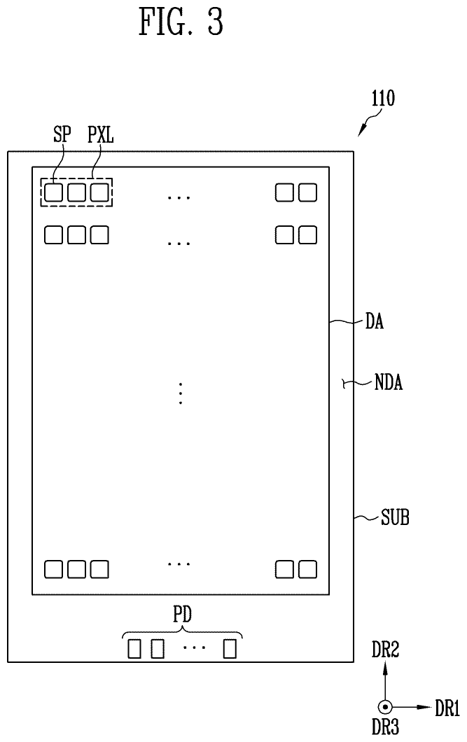

FIG. 3 is a plan view illustrating further details of the display panel of FIG. 1 according to some embodiments.

Referring to FIG. 3, according to some embodiments, the display panel 110 of FIG. 1 may include a display area DA and a non-display area NDA. The display panel 110 may display images through the display area DA. The non-display area NDA may be arranged around (e.g., in a periphery or outside a footprint of) the display area DA.

The display panel 110 may include a substrate SUB, the sub-pixels SP, and pads PD.

When the display panel 110 is used as a display screen of a head mounted display (HMD), a virtual reality (VR) device, a mixed reality (MR) device, an augmented reality (AR) device, or the like, the display panel 110 may be positioned very close to user's eyes. In this case, sub-pixels SP of a relatively high integration degree may be required. In order to increase an integration degree of the sub-pixels SP, the substrate SUB may be provided as a silicon substrate. The sub-pixels SP and/or the display panel 110 may be formed on the substrate SUB, which is the silicon substrate. The display device 100 (refer to FIG. 1) including the display panel 110 formed on the substrate SUB, which is the silicon substrate, may be referred to as an OLED on silicon (OLEDoS) display device.

The sub-pixels SP may be located in the display area DA on the substrate SUB. The sub-pixels SP may be arranged in a matrix shape along a first direction DR1 and a second direction DR2 crossing the first direction DR1. However, embodiments according to the present disclosure are not limited thereto. For example, the sub-pixels SP may be arranged in a zigzag shape along the first direction DR1 and the second direction DR2. For example, the sub-pixels SP may be arranged in a PENTILE™ shape. The first direction DR1 may be a row direction, and the second direction DR2 may be a column direction.

Two or more sub-pixels among the plurality of sub-pixels SP may configure one pixel PXL.

A component for controlling the sub-pixels SP may be located in the non-display area NDA on the substrate SUB. For example, lines connected to the sub-pixels SP, such as the first to m-th gate lines GL1 to GLm and the first to n-th data lines DL1 to DLn of FIG. 1, may be located in the non-display area NDA.

At least one of the gate driver 120, the data driver 130, the voltage generator 140, the controller 150, or the temperature sensor 160 of FIG. 1 may be integrated in the non-display area NDA of the display panel 110. According to some embodiments, the gate driver 120 of FIG. 1 may be mounted on the display panel 110 and may be located in the non-display area NDA. According to some embodiments, the gate driver 120 may be implemented as an integrated circuit separated from the display panel 110. According to some embodiments, the temperature sensor 160 may be located in the non-display area NDA to sense a temperature of the display panel 110.

The pads PD may be located in the non-display area NDA on the substrate SUB. The pads PD may be electrically connected to the sub-pixels SP through lines. For example, the pads PD may be connected to the sub-pixels SP through the first to n-th data lines DL1 to DLn.

The pads PD may interface the display panel 110 to other components of the display device 100 (refer to FIG. 1). According to some embodiments, voltages and signals necessary for an operation of components included in the display panel 110 may be provided from the driver integrated circuit DIC of FIG. 1 through the pads PD. For example, the first to n-th data lines DL1 to DLn may be connected to the driver integrated circuit DIC through the pads PD. For example, the first and second power voltages VDD and VSS may be received from the driver integrated circuit DIC through the pads PD. For example, when the gate driver 120 is mounted on the display panel 110, the gate control signal GCS may be transmitted from the driver integrated circuit DIC to the gate driver 120 through the pads PD.

According to some embodiments, a circuit board may be electrically connected to the pads PD using a conductive adhesive member such as an anisotropic conductive film. At this time, the circuit board may be a flexible circuit board (FPCB) or a flexible film having a flexible material. The driver integrated circuit DIC may be mounted on the circuit board to be electrically connected to the pads PD.

According to some embodiments, the display area DA may have various shapes. The display area DA may have a closed loop shape including straight and/or curved sides. For example, the display area DA may have shapes such as a polygon, a circle, a semicircle, and an ellipse.

According to some embodiments, the display panel 110 may have a flat display surface. According to some embodiments, the display panel 110 may have a display surface that is at least partially round. According to some embodiments, the display panel 110 may be bendable, foldable, or rollable. In these cases, the display panel 110 and/or the substrate SUB may include materials having a flexible property.

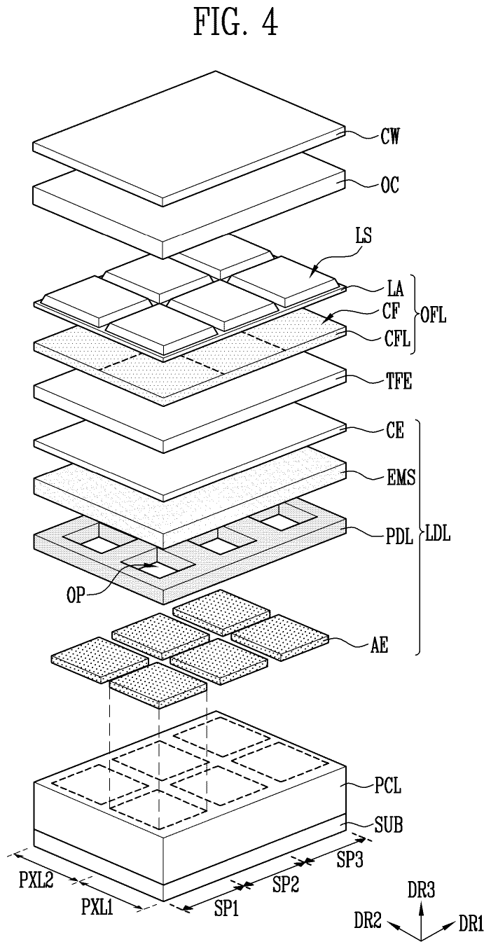

FIG. 4 is an exploded perspective view illustrating a portion of the display panel of FIG. 3. In FIG. 4, for clear and concise description, a portion of the display panel 110 corresponding to two pixels PXL1 and PXL2 among the pixels PXL of FIG. 3 is schematically shown. A portion of the display panel 110 corresponding to remaining pixels may be similarly configured.

Referring to FIGS. 3 and 4, each of the first and second pixels PXL1 and PXL2 may include first to third sub-pixels SP1, SP2, and SP3. However, embodiments are not limited thereto. For example, each of the first and second pixels PXL1 and PXL2 may include four sub-pixels or two sub-pixels.

In FIG. 4, the first to third sub-pixels SP1, SP2, and SP3 have quadrangle shapes when viewed from a third direction DR3 crossing the first and second directions DR1 and DR2, and have sizes equal to each other. However, embodiments according to the present disclosure are not limited thereto. The first to third sub-pixels SP1, SP2, and SP3 may be modified to have various shapes.

The display panel 110 may include the substrate SUB, a pixel circuit layer PCL, a light emitting element layer LDL, an encapsulation layer TFE, an optical functional layer OFL, an overcoat layer OC, and a cover window CW.

According to some embodiments, the substrate SUB may include a silicon wafer substrate formed using a semiconductor process. The substrate SUB may include a semiconductor material suitable for forming circuit elements. For example, the semiconductor material may include silicon, germanium, and/or silicon-germanium. The substrate SUB may be provided from a bulk wafer, an epitaxial layer, a silicon on insulator (SOI) layer, a semiconductor on insulator (SeOI) layer, or the like. According to some embodiments, the substrate SUB may include a glass substrate. In still other embodiments, the substrate SUB may include a polyimide (PI) substrate.

The pixel circuit layer PCL may be located on the substrate SUB. The substrate SUB and/or the pixel circuit layer PCL may include insulating layers and conductive patterns located between the insulating layers. The conductive patterns of the pixel circuit layer PCL may function as at least a portion of circuit elements, lines, and the like. The conductive patterns may include copper, but embodiments according to the present disclosure are not limited thereto.

The circuit elements may include the sub-pixel circuit SPC (refer to FIG. 2) for each of the first to third sub-pixels SP1, SP2, and SP3. The sub-pixel circuit SPC may include transistors and one or more capacitors. Each transistor may include a semiconductor portion including a source area, a drain area, and a channel area, and a gate electrode overlapping the semiconductor portion. According to some embodiments, when the substrate SUB is provided as a silicon substrate, the semiconductor portion may be included in the substrate SUB, and the gate electrode may be included in the pixel circuit layer PCL as a conductive pattern of the pixel circuit layer PCL. According to some embodiments, when the substrate SUB is provided as a glass substrate or a PI substrate, the semiconductor portion and the gate electrode may be included in the pixel circuit layer PCL. Each capacitor may include electrodes spaced apart from each other. For example, each capacitor may include electrodes spaced apart from each other on a plane defined by the first and second directions DR1 and DR2. For example, each capacitor may include electrodes spaced apart from each other in the third direction DR3 with an insulating layer interposed therebetween.

The lines of the pixel circuit layer PCL may include signal lines connected to each of the first to third sub-pixels SP1, SP2, and SP3, for example, a gate line, an emission control line, a data line, and the like. The lines may further include a line connected to the first power voltage node VDDN of FIG. 2. In addition, the lines may further include a line connected to the second power voltage node VSSN of FIG. 2.

The light emitting element layer LDL may include the anode electrodes AE, a pixel defining layer PDL, a light emitting structure EMS, and the cathode electrode CE.

The anode electrodes AE may be located on the pixel circuit layer PCL. The anode electrodes AE may contact the circuit elements of the pixel circuit layer PCL. The anode electrodes AE may include an opaque conductive material capable of reflecting light, but embodiments according to the present disclosure are not limited thereto.

The pixel defining layer PDL may be located on the anode electrodes AE. The pixel defining layer PDL may include an opening OP exposing a portion of each of the anode electrodes AE. The opening OP of the pixel defining layer PDL may be understood as emission areas corresponding to the first to third sub-pixels SP1 to SP3, respectively.

According to some embodiments, the pixel defining layer PDL may include an inorganic material. In this case, the pixel defining layer PDL may include a plurality of stacked inorganic layers. For example, the pixel defining layer PDL may include silicon oxide SiOx and silicon nitride SiNx. According to some embodiments, the pixel defining layer PDL may include an organic material. However, a material of the pixel defining layer PDL is not limited thereto.

The light emitting structure EMS may be located on the anode electrodes AE exposed by the opening OP of the pixel defining layer PDL. The light emitting structure EMS may include a light emitting layer configured to generate light, an electron transport layer configured to transport an electron, a hole transport layer configured to transport a hole, and the like.

According to some embodiments, the light emitting structure EMS may fill the opening OP of the pixel defining layer PDL, and may be entirely arranged or formed on the pixel defining layer PDL. In other words, the light emitting structure EMS may extend across the first to third sub-pixels SP1 to SP3. In this case, at least a portion of layers in the light emitting structure EMS may be disconnected or bent at boundaries between the first to third sub-pixels SP1 to SP3. However, embodiments according to the present disclosure are not limited thereto. For example, portions of the light emitting structure EMS corresponding to the first to third sub-pixels SP1 to SP3 may be separated from each other, and each of the portions may be located in the opening OP of the pixel defining layer PDL.

The cathode electrode CE may be located on the light emitting structure EMS. The cathode electrode CE may extend across the first to third sub-pixels SP1 to SP3. As described above, the cathode electrode CE may be provided as a common electrode for the first to third sub-pixels SP1 to SP3.

The cathode electrode CE may be a thin metal layer having a thickness sufficient to transmit light emitted from the light emitting structure EMS. The cathode electrode CE may be formed of a metal material or a transparent conductive material to have a relatively thin thickness. According to some embodiments, the cathode electrode CE may include at least one of various transparent conductive materials including indium tin oxide, indium zinc oxide, indium tin zinc oxide, aluminum zinc oxide, gallium zinc oxide, zinc tin oxide, or gallium tin oxide. According to some embodiments, the cathode electrode CE may include at least one of silver (Ag), magnesium (Mg), and/or a mixture thereof. However, a material of the cathode electrode CE is not limited thereto.

It may be understood that any one of the anode electrodes AE, a portion of the light emitting structure EMS overlapping it, and a portion of the cathode electrode CE overlapping it configure one light emitting element LD (refer to FIG. 2). In other words, each of the light emitting elements of the first to third sub-pixels SP1 to SP3 may one anode electrode, a portion of the light emitting structure EMS overlapping it, and a portion of the cathode electrode CE overlapping it. In each of the first to third sub-pixels SP1 to SP3, holes injected from the anode electrode AE and electrons injected from the cathode electrode CE may be transported into the light emitting layer of the light emitting structure EMS to form excitons, and when the excitons transits from an excited state to a ground state, light may be generated. A luminance of light may be determined according to an amount of a current flowing through the light emitting layer. According to a configuration of the light emitting layer, a wavelength range of the generated light may be determined.

The encapsulation layer TFE may be located on the cathode electrode CE. The encapsulation layer TFE may cover the light emitting element layer LDL and/or the pixel circuit layer PCL. The encapsulation layer TFE may be configured to prevent or reduce instances of contaminants such as oxygen, moisture, and/or the like permeating to the light emitting element layer LDL. According to some embodiments, the encapsulation layer TFE may include a structure in which one or more inorganic layers and one or more organic layers are alternately stacked. For example, the inorganic layer may include silicon nitride, silicon oxide, silicon oxynitride (SiOxNy), or the like. For example, the organic layer may include an organic insulating material such as acrylic resin, epoxy resin, phenol resin, polyamide resin, polyimide resin, unsaturated polyester resin, polyphenylenether resin, polyphenylenesulfide resin, or benzocyclobutene (BCB). However, materials of the organic layer and the inorganic layer of the encapsulation layer TFE are not limited thereto.

In order to relatively improve encapsulation efficiency of the encapsulation layer TFE, the encapsulation layer TFE may further include a thin film including aluminum oxide (AIOx). The thin film including the aluminum oxide may be positioned on an upper surface of the encapsulation layer TFE facing the optical functional layer OFL and/or a lower surface of the encapsulating layer TFE facing the light emitting element layer LDL.

The thin film including the aluminum oxide may be formed through atomic layer deposition (ALD) method. However, embodiments according to the present disclosure are not limited thereto. The encapsulation layer TFE may further include a thin film formed of at least one of various materials suitable for relatively improving the encapsulation efficiency.

The optical functional layer OFL may be located on the encapsulation layer TFE. The optical functional layer OFL may include a color filter layer CFL and a lens array LA.

The color filter layer CFL may be located between the encapsulation layer TFE and the lens array LA. The color filter layer CFL may be configured to filter the light emitted from the light emitting structure EMS and selectively output light of a wavelength range or a color corresponding to each sub-pixel. The color filter layer CFL may include color filters CF respectively corresponding to the first to third sub-pixels SP1 to SP3, and each of the color filters CF may pass light of a wavelength range corresponding to the corresponding sub-pixel. For example, the color filter corresponding to the first sub-pixel SP1 may pass red color light, the color filter corresponding to the second sub-pixel SP2 may pass green color light, and the color filter corresponding to the third sub-pixel SP3 may pass blue color light. According to the light emitted from the light emitting structure EMS of each sub-pixel, at least a portion of the color filters CF may be omitted.

The lens array LA may be located on the color filter layer CFL. The lens array LA may include lenses LS respectively corresponding to the first to third sub-pixels SP1 to SP3. Each of the lenses LS may relatively improve light output efficiency by outputting the light emitted from the light emitting structure EMS to an intended path. The lens array LA may have a relatively high refractive index. For example, the lens array LA may have a refractive index higher than that of the overcoat layer OC. According to some embodiments, the lenses LS may include an organic material. According to some embodiments, the lenses LS may include an acrylic material. However, a material of the lenses LS is not limited thereto.

According to some embodiments, compared to the opening OP of the pixel defining layer PDL, at least a portion of the color filters CF of the color filter layer CFL and at least a portion of the lenses LS of the lens array LA may be shifted in a direction parallel to the plane defined by the first and second directions DR1 and DR2. For example, in a central area of the display area DA, a center of the color filter and a center of the lens may be aligned with or overlap with a center of the opening OP of the corresponding pixel definition layer PDL when viewed in the third direction DR3. For example, in the central area of the display area DA, the opening OP of the pixel defining layer PDL may completely overlap the corresponding color filter of the color filter layer CFL and the corresponding lens of the lens array LA. In an area adjacent to the non-display area NDA in the display area DA, the center of the color filter and the center of the lens may be shifted in a plane direction from the center of the opening OP of the corresponding pixel defining layer PDL when viewed in the third direction DR3 (e.g., in a plan view). For example, in the area adjacent to the non-display area NDA in the display area DA, the opening OP of the pixel defining layer PDL may be partially overlap of the corresponding color filter of the color filter layer CFL and the corresponding lens of the lens array LA. Accordingly, at a center of the display area DA, the light emitted from the light emitting structure EMS may be efficiently output in a normal direction of a display surface. At an outskirt of the display area DA, the light emitted from the light emitting structure EMS may be efficiently output in a direction inclined by an angle (e.g., a set or predetermined angle) with respect to the normal direction of the display surface.

The overcoat layer OC may be located on the lens array LA. The overcoat layer OC may cover the optical functional layer OFL, the encapsulation layer TFE, the light emitting structure EMS, and/or the pixel circuit layer PCL. The overcoat layer OC may include various materials suitable for protecting layers thereunder from a foreign substance such as dust or moisture. For example, the overcoat layer OC may include at least one of an inorganic insulating layer or an organic insulating layer. For example, the overcoat layer OC may include epoxy, but embodiments are not limited thereto. The overcoat layer OC may have a refractive index lower than that of the lens array LA.

The cover window CW may be located on the overcoat layer OC. The cover window CW may be configured to protect layers thereunder. The cover window CW may have a refractive index higher than that of the overcoat layer OC. The cover window CW may include glass, but embodiments are not limited thereto. For example, the cover window CW may be an encapsulation glass configured to protect components located thereunder. According to some embodiments, the cover window CW may be omitted.

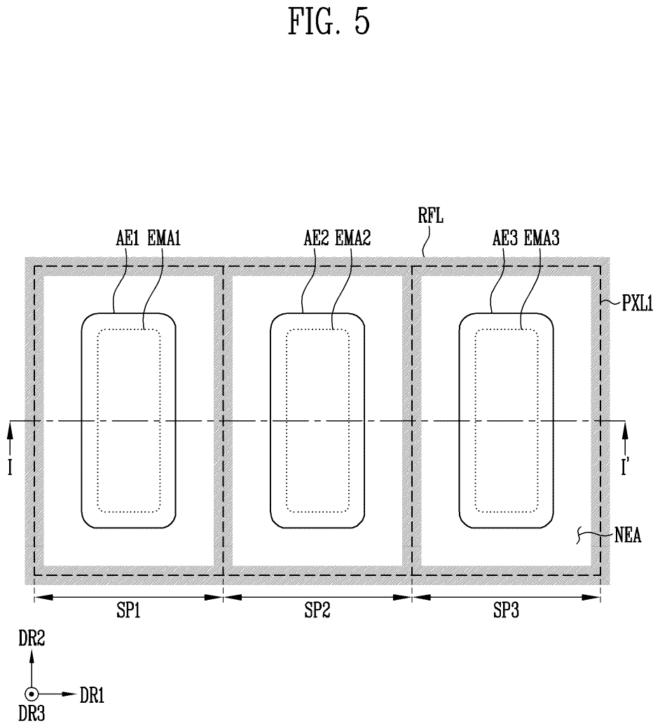

FIG. 5 is a plan view illustrating aspects of a pixel of FIG. 4 according to 1 some embodiments. In FIG. 5, the first pixel PXL1 of the first and second pixels PXL1 and PXL2 of FIG. 4 is schematically shown for clear and concise description. The remaining pixels may be configured similarly to the first pixel PXL1.

Referring to FIGS. 4 and 5, the first and second pixels PXL1 and PXL2 may include the first to third sub-pixels SP1 to SP3 arranged in the first direction DR1.

The first sub-pixel SP1 may include a first anode electrode AE1. The second sub-pixel SP2 may include a second anode electrode AE2. The third sub-pixel SP3 may include a third anode electrode AE3.

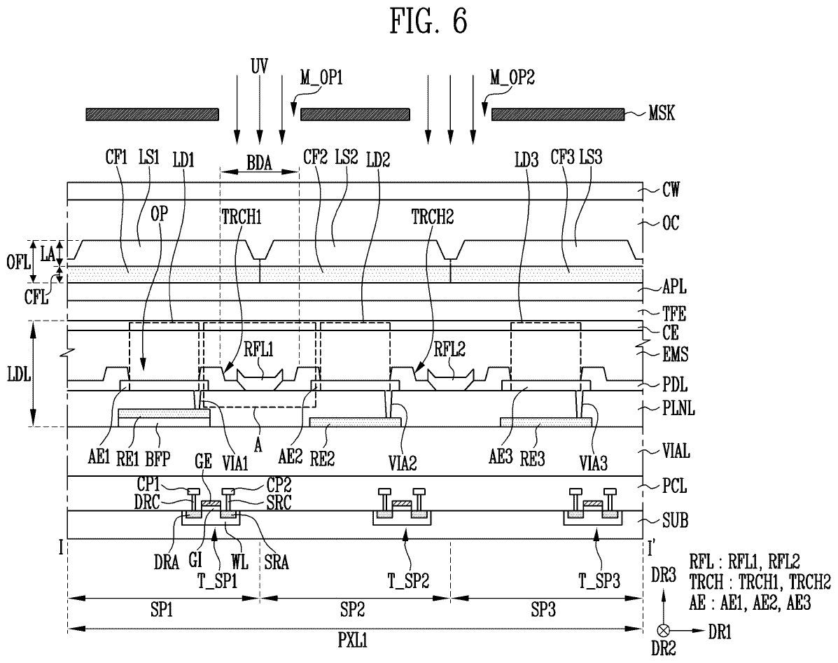

The first pixel PXL1 may include a reflective layer RFL in a boundary area BDA (refer to FIG. 6) between the first to third sub-pixels SP1 to SP3. The reflective layer RFL may be arranged along a circumference of the first anode electrode AE1 in the first sub-pixel SP1. The reflective layer RFL may be arranged along a circumference of the second anode electrode AE2 in the second sub-pixel SP2. The reflective layer RFL may be arranged along a circumference of the third anode electrode AE3 in the third sub-pixel SP3. In addition, a portion of the reflective layer RFL may be located between the first anode electrode AE1 and the second anode electrode AE2. Another portion of the reflective layer RFL may be located between the second anode electrode AE2 and the third anode electrode AE3.

The first sub-pixel SP1 may include a first emission area EMA1 and a non-emission area NEA around the first emission area EMA1. The first emission area EMA1 may be positioned in the first anode electrode AE1, and at least a portion may extend to the non-emission area NEA. The second sub-pixel SP2 may include a second emission area EMA2 and a non-emission area NEA around the second emission area EMA2. The second emission area EMA2 may be positioned in the second anode electrode AE2, and at least a portion may extend to the non-emission area NEA. The third sub-pixel SP3 may include a third emission area EMA3 and a non-emission area NEA around the third emission area EMA3. The third emitting area EMA3 may be positioned in the third anode electrode AE3, and at least a portion may extend to the non-emission area NEA.

The first emission area EMA1 may be an area where light is emitted from a portion of the light emitting structure EMS (refer to FIG. 4) corresponding to the first sub-pixel SP1. The second emission area EMA2 may be an area where light is emitted from a portion of the light emitting structure EMS corresponding to the second sub-pixel SP2. The third emission area EMA3 may be an area where light is emitted from a portion of the light emitting structure EMS corresponding to the third sub-pixel

SP3. As described with reference to FIG. 5, each emission area may be understood as the opening OP of the pixel defining layer PDL corresponding to each of the first to third sub-pixels SP1 to SP3.

FIG. 6 is a cross-sectional view taken along a line I-I′ of FIG. 5.

Referring to FIG. 6, the substrate SUB and the pixel circuit layer PCL located on the substrate SUB may be provided.

The substrate SUB may include a silicon wafer substrate formed using a semiconductor process. For example, the substrate SUB may include silicon, germanium, and/or silicon-germanium.

The pixel circuit layer PCL may be located on the substrate SUB. The substrate SUB and the pixel circuit layer PCL may include circuit elements of each of the first to third sub-pixels SP1 to SP3. For example, the substrate SUB and the pixel circuit layer PCL may include a transistor T_SP1 of the first sub-pixel SP1, a transistor T_SP2 of the second sub-pixel SP2, and a transistor T_SP3 of the third sub-pixel SP3. The transistor T_SP1 of the first sub-pixel SP1 may be any one of the transistors included in the sub-pixel circuit SPC (refer to FIG. 2) of the first sub-pixel SP1, the transistor T_SP2 of the second sub-pixel SP2 may be any one of the transistors included in the sub-pixel circuit SPC of the second sub-pixel SP2, and the transistor T_SP3 of the third sub-pixel SP3 may be any one of the transistors included in the sub-pixel circuit SPC of the third sub-pixel SP3. In FIG. 6, for clear and concise description, one of the transistors of each sub-pixel is shown, and the remaining circuit elements are omitted.

The transistor T_SP1 of the first sub-pixel SP1 may include a source area SRA, a drain area DRA, and a gate electrode GE.

The source area SRA and drain area DRA may be located in the substrate SUB. A well WL formed through an ion injection process may be located in the substrate SUB, and the source area SRA and the drain area DRA may be arranged to be spaced apart from each other in the well WL. An area between the source area SRA and the drain area DRA in the well WL may be defined as a channel area.

The gate electrode GE may overlap the channel area between the source area SRA and the drain area DRA and may be located in the pixel circuit layer PCL. The gate electrode GE may be spaced apart from the well WL or the channel area by an insulating material such as a gate insulating layer GI. The gate electrode GE may include a conductive material.

A plurality of layers included in the pixel circuit layer PCL may include insulating layers and conductive patterns located between the insulating layers, and such conductive patterns may include first and second conductive patterns CP1 and CP2. The first conductive pattern CP1 may be electrically connected to the drain area DRA through a drain connection portion DRC passing through one or more insulating layers. The second conductive pattern CP2 may be electrically connected to the source area SRA through a source connection portion SRC passing through one or more insulating layers.

As the gate electrode GE and the first and second conductive patterns CP1 and CP2 are connected to different circuit elements and/or lines, the transistor T_SP1 of the first sub-pixel SP1 may be provided as any one of the transistors of the first sub-pixel SP1.

Each of the transistor T_SP2 of the second sub-pixel SP2 and the transistor T_SP3 of the third sub-pixel SP3 may be configured similarly to the transistor T_SP1 of the first sub-pixel SP1.

As described above, the substrate SUB and the pixel circuit layer PCL may include the circuit elements of each of the first to third sub-pixels SP1 to SP3.

A via layer VIAL may be located on the pixel circuit layer PCL. The via layer VIAL may cover the pixel circuit layer PCL and may have an overall flat surface. The via layer VIAL may be configured to planarize steps on the pixel circuit layer PCL. The via layer VIAL may include at least one of silicon oxide (SiOx), silicon nitride (SiNx), or silicon carbon nitride (SiCN), but embodiments according to the present disclosure are not limited thereto.

The light emitting element layer LDL may be located on the via layer VIAL. The light emitting element layer LDL may include first to third reflective electrodes RE1 to RE3, a planarization layer PLNL, first to third anode electrodes AE1 to AE3, the pixel defining layer PDL, the light emitting structure EMS, and the cathode electrode CE.

On the via layer VIAL, the first to third reflective electrodes RE1 to RE3 may be located in the first to third sub-pixels SP1 to SP3, respectively. Each of the first to third reflective electrodes RE1 to RE3 may contact the circuit element located in the pixel circuit layer PCL through a via passing through the via layer VIAL.

The first to third reflective electrodes RE1 to RE3 may function as a full mirror reflecting the light emitted from the light emitting structure EMS toward the display surface (or the cover window CW). The first to third reflective electrodes RE1 to RE3 may include metal materials suitable for reflecting light. The first to third reflective electrodes RE1 to RE3 may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), and/or an alloy of two or more materials selected from them, but embodiments are not limited thereto.

According to some embodiments, a connection electrode may be located under each of the first to third reflective electrodes RE1 to RE3. The connection electrode may relatively improve an electrical connection characteristic between a corresponding reflective electrode and the circuit element of the pixel circuit layer PCL. The connection electrode may have a multilayer structure. The multilayer structure may include titanium (Ti), titanium nitride (TiN), tantalum nitride (TaN), or the like, but embodiments are not limited thereto. According to some embodiments, a corresponding reflective electrode may be positioned between multiple layers of the connection electrode.

A buffer pattern BFP may be located under at least one of the first to third reflective electrodes RE1 to RE3. The buffer pattern BFP may include an inorganic material such as silicon carbon nitride, but embodiments according to the present disclosure are not limited thereto. By forming the buffer pattern BFP, a height of the third direction DR3 of a corresponding reflective electrode may be adjusted. For example, the buffer pattern BFP may be located between the first reflective electrode RE1 and the via layer VIAL to adjust a height of the first reflective electrode RE1.

The first to third reflective electrodes RE1 to RE3 may function as full mirrors, and the cathode electrode CE may function as a half mirror. The light emitted from the light emitting layer of the light emitting structure EMS may be amplified by at least partially reciprocating between a corresponding reflective electrode and the cathode electrode CE, and the amplified light may be output through the cathode electrode CE. As described above, a distance between each reflective electrode and the cathode electrode CE may be understood as a resonance distance for the light emitted from the light emitting layer of the corresponding light emitting structure EMS.

The first sub-pixel SP1 may have a resonance distance shorter than that of another sub-pixel by the buffer pattern BFP. The resonance distance adjusted as described above may allow light of a specific wavelength range (for example, red color) to be effectively and efficiently amplified. Accordingly, the first sub-pixel SP1 may effectively and efficiently output light of a corresponding wavelength range.

In FIG. 6, the buffer pattern BFP is provided to the first sub-pixel SP1 and is not provided to the second and third sub-pixels SP2 and SP3, but embodiments are not limited thereto. The buffer pattern may also be provided to at least one of the second or third sub-pixels SP2 or SP3 to adjust the resonance distance of at least one of the second or third sub-pixels SP2 or SP3. For example, the buffer pattern BFP may also be provided to the second sub-pixel SP2, and the resonance distance of the second sub-pixel SP2 may be adjusted. For example, the first to third sub-pixels SP1 to SP3 may correspond to red, green, and blue, respectively, a distance between the first reflective electrode RE1 and the cathode electrode CE may be shorter than a distance between the second reflective electrode RE2 and the cathode electrode CE, and the distance between the second reflective electrode RE2 and the cathode electrode CE may be shorter than a distance between the third reflective electrode RE3 and the cathode electrode CE.

In order to planarize steps between the first to third reflective electrodes RE1 to RE3, a planarization layer PLNL may be located on the via layer VIAL and the first to third reflective electrodes RE1 to RE3. The planarization layer PLNL may generally cover the first to third reflective electrodes RE1 to RE3 and the via layer VIAL, and may have a flat surface. According to some embodiments, the planarization layer PLNL may be omitted.

On the planarization layer PLNL, the first to third anode electrodes AE1 to AE3 respectively overlapping the first to third reflective electrodes RE1 to RE3 may be arranged. The first to third anode electrodes AE1 to AE3 may have shapes similar to those of the first to third emission areas EMA1 to EMA3 of FIG. 6 when viewed in the third direction DR3 (e.g., in a plan view). The first to third anode electrodes AE1 to AE3 may be respectively connected to the first to third reflective electrodes RE1 to RE3. The first anode electrode AE1 may be connected to the first reflective electrode RE1 through a first via VIA1 passing through the planarization layer PLNL. The second anode electrode AE2 may be connected to the second reflective electrode RE2 through a second via VIA2 passing through the planarization layer PLNL. The third anode electrode AE3 may be connected to the third reflective electrode RE3 through a third via VIA3 passing through the planarization layer PLNL.

According to some embodiments, the first to third anode electrodes AE1 to AE3 may include at least one of transparent conductive materials such as indium tin oxide (ITO), indium zinc oxide (IZO), zinc oxide (ZnOₓ), indium gallium zinc oxide (IGZO), or indium tin zinc oxide (ITZO). However, a material of the first to third anode electrodes AE1 to AE3 is not limited thereto. For example, the first to third anode electrodes AE1 to AE3 may include titanium nitride.

According to some embodiments, insulating layers for adjusting a height of one or more of the first to third anode electrodes AE1 to AE3 may be further provided. The insulating layers may be located between one or more of the first to third anode electrodes AE1 to AE3 and corresponding reflective electrodes. In this case, the planarization layer PLNL and/or the buffer pattern BFP may be omitted. For example, the first to third sub-pixels SP1 to SP3 may correspond to red, green, and blue, respectively, a distance between the first anode electrode AE1 and the cathode electrode CE may be shorter than a distance between the second anode electrode AE2 and the cathode electrode CE, and the distance between the second anode electrode AE2 and the cathode electrode CE may be shorter than a distance between the third anode electrode AE3 and the cathode electrode CE.

The pixel defining layer PDL may be located on portions of the first to third anode electrodes AE1 to AE3 and the planarization layer PLNL. The pixel defining layer PDL may include an opening OP exposing a portion of each of the first to third anode electrodes AE1 to AE3. The opening OP of the pixel defining layer PDL may define the emission area of each of the first to third sub-pixels SP1 to SP3. As described above, the pixel defining layer PDL may be located in the non-emission area NEA of FIG. 5 and may define the first to third emission areas EMA1 to EMA3 of FIG. 5.

The pixel defining layer PDL may have a recessed shape arranged to surround the first to third anode electrodes AE1 to AE3. Here, the recessed shape may be trenches TRCH. Hereinafter, the recessed shape in FIG. 6 is described using a trench as an example, but the recessed shape is not limited to the trench.

Referring to FIG. 6, the trenches TRCH may include a first trench TRCH1 and a second trench TRCH2. The first trench TRCH1 may be located in the boundary area BDA between the first sub-pixel SP1 and the second sub-pixel SP2. The second trench TRCH2 may be located in the boundary area between the second sub-pixel SP2 and the third sub-pixel SP3. However, embodiments are not limited thereto. For example, the pixel defining layer PDL may include two or more trenches in the boundary area BDA.

According to some embodiments, as shown in FIG. 6, the first and second trenches TRCH1 and TRCH2 may partially pass through the pixel defining layer PDL. According to some embodiments, the first and second trenches TRCH1 and TRCH2 may completely pass through the pixel defining layer PDL. In this case, the first and second trenches TRCH1 and TRCH2 may partially pass through the planarization layer PLNL.

The first and second trenches TRCH1 and TRCH2 may cause formation of a discontinuous portion (discontinuity) in the light emitting structure EMS in the boundary area BDA. The light emitting structure EMS may have the discontinuous portion in areas overlapping the first and second trenches TRCH1 and TRCH2. Due to the discontinuity, a portion of layers of the light emitting structure EMS may be electrically disconnected at the boundary area BDA.

According to some embodiments, the pixel defining layer PDL may include a plurality of inorganic insulating layers. Each of the plurality of inorganic insulating layers may include at least one of silicon oxide (SiOx) or silicon nitride (SiNx). For example, the pixel defining layer PDL may include sequentially stacked first to third inorganic insulating layers, and each of the first to third inorganic insulating layers may include silicon nitride, silicon oxide, and silicon nitride. However, embodiments according to the present disclosure are not limited thereto. The first to third inorganic insulating layers may have a step shape of cross-section in an area adjacent to the opening OP of the pixel defining layer PDL.

A reflective layer RFL may be located in the boundary area BDA between the sub-pixels adjacent to each other. In other words, the reflective layer RFL may be located in each of the boundary areas between the sub-pixels SP of FIG. 5.

The reflective layer RFL may be provided in or on the pixel defining layer PDL. The pixel defining layer PDL may include the reflective layer RFL overlapping one or more trenches TRCH in the boundary area BDA. The pixel defining layer PDL may include a first reflective layer RFL1 overlapping the first trench TRCH1. The pixel defining layer PDL may include a second reflective layer RFL2 overlapping the second trench TRCH2.

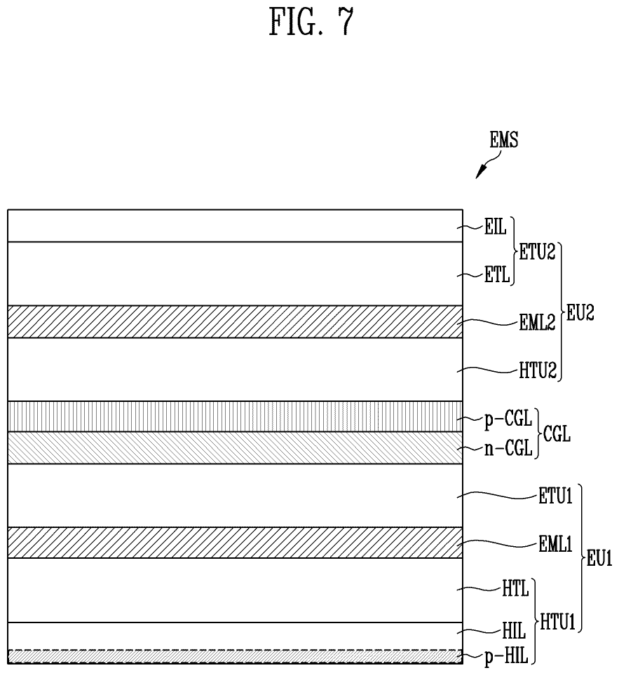

In a manufacturing process, a mask MSK having openings M_OP1 and M_OP2 may be arranged. The openings M_OP1 and M_OP2 of the mask MSK may overlap the first and second reflective layers RFL1 and RFL2. Subsequently, ultraviolet rays UV may be irradiated through the openings M_OP1 and M_OP2. The ultraviolet rays UV may cause a portion overlapping the openings M_OP1 and M_OP2 of the light emitting structure EMS to further have discontinuous portions. A portion of a plurality of layers stacked in the light emitting structure EMS may be disconnected or denatured by the ultraviolet rays UV. For example, at least one charge generation layer CGL (refer to FIG. 7) included in the light emitting structure EMS may be disconnected in an area overlapping the first and second reflective layers RFL1 and RFL2. At least one p-hole injection layer p-HIL (refer to FIG. 7) included in the light emitting structure EMS may be disconnected in an area overlapping the first and second reflective layers RFL1 and RFL2. In the disclosure, the charge generation layer CGL and the p-hole injection layer p-HIL are described as an example, but the disclosure is not limited thereto. For example, at least one layer among first and second hole transport units HTU1 and HTU2, first and second electron transport units ETU1 and ETU2, and first and second light emitting layers EML1 and EML2 included in the light emitting structure EMS may be disconnected in an area overlapping the first and second reflective layers RFL1 and RFL2. As another example, a plurality of layers included in the light emitting structure EMS may be disconnected in an area overlapping the first and second reflective layers RFL1 and RFL2.

The reflective layer RFL may be provided as a reflect plate that reflects the ultraviolet rays UV. According to some embodiments, the first and second reflective layers RFL1 and RFL2 may be formed of the same material as the anode electrodes. For example, the first and second reflective layers RFL1 and RFL2 may have a shape recessed in a direction opposite to the third direction DR3. According to the shape of the reflective layer RFL, a portion of the plurality of layers stacked in the light emitting structure EMS may be disconnected with a small amount of ultraviolet rays UV. In addition, an area to which the ultraviolet UV rays are irradiated may be minimized.

According to some embodiments, the light emitting structure EMS may be formed through a process of vacuum deposition, inkjet printing, and the like. In this case, in the first and second trenches TRCH1 and TRCH2, the same materials as the light emitting structure EMS may be positioned on bottom surfaces adjacent to the planarization layer PLNL.

The light emitting structure EMS may be located on the anode electrode AE exposed by the opening OP of the pixel defining layer PDL. The light emitting structure EMS may fill the opening OP of the pixel defining layer PDL and may be arranged entirely across the first to third sub-pixels SP1 to SP3. As described above, at least a portion of the light emitting structure EMS may be disconnected in the boundary area BDA by the first and second trenches TRCH1 and TRCH2 and the ultraviolet rays UV.

Accordingly, when the display panel 110 is operated, a current flowing out from each of the first to third sub-pixels SP1 to SP3 to the neighboring sub-pixel through the layers included in the light emitting structure EMS may be reduced. Therefore, the first to third light emitting elements LD1 to LD3 may operate with relatively high reliability.

The cathode electrode CE may be located on the light emitting structure EMS. The cathode electrode CE may be commonly provided to the first to third sub-pixels SP1 to SP3. The cathode electrode CE may function as a half mirror that partially transmits and partially reflects the light emitted from the light emitting structure EMS.

The first anode electrode AE1, a portion of the light emitting structure EMS overlapping the first anode electrode AE1, and a portion of the cathode electrode CE overlapping the first anode electrode AE1 may configure the first light emitting element LD1. The second anode electrode AE2, a portion of the light emitting structure EMS overlapping the second anode electrode AE2, and a portion of the cathode electrode CE overlapping the second anode electrode AE2 may configure the second light emitting element LD2. The third anode electrode AE3, a portion of the light emitting structure EMS overlapping the third anode electrode AE3, and a portion of the cathode electrode CE overlapping the third anode electrode AE3 may configure the third light emitting element LD3.

The encapsulation layer TFE may be located on the cathode electrode CE. The encapsulation layer TFE may prevent or reduce instances of contaminants such as oxygen, moisture, and/or the like permeating to the light emitting element layer LDL.

The optical functional layer OFL may be located on the encapsulation layer TFE. According to some embodiments, the optical functional layer OFL may be attached to the encapsulation layer TFE through an adhesive layer APL. For example, the optical functional layer OFL may be separately manufactured and attached to the encapsulation layer TFE through the adhesive layer APL. The adhesive layer APL may further perform a function of protecting lower layers including the encapsulation layer TFE.

The optical functional layer OFL may include the color filter layer CFL and the lens array LA. The color filter layer CFL may include first to third color filters CF1 to CF3 respectively corresponding to the first to third sub-pixels SP1 to SP3. The first to third color filters CF1 to CF3 may pass light of different wavelength ranges. For example, the first to third color filters CF1 to CF3 may pass light of red, green, and blue colors, respectively.

According to some embodiments, the first to third color filters CF1 to CF3 may partially overlap in the boundary area BDA. According to some embodiments, the first to third color filters CF1 to CF3 may be spaced apart from each other, and a black matrix may be provided between the first to third color filters CF1 to CF3.

The lens array LA may be located on the color filter layer CFL. The lens array LA may include first to third lenses LS1 to LS3 respectively corresponding to the first to third sub-pixels SP1 to SP3. Each of the first to third lenses LS1 to LS3 may relatively improve light output efficiency by outputting light emitted from the first to third light emitting elements LD1 to LD3 to an intended path.

The overcoat layer OC and the cover window CW may be located on the lens array LA.

FIG. 7 is a cross-sectional view illustrating aspects of a light emitting structure included in any one of the first to third light emitting elements of FIG. 6 according to some embodiments.

Referring to FIG. 7, the light emitting structure EMS may have a tandem structure in which first and second light emitting units EU1 and EU2 are stacked. The light emitting structure EMS may be configured substantially equally in each of the first to third light emitting elements LD1 to LD3.

Each of the first and second light emitting units EU1 and EU2 may include at least one light emitting layer that generates light according to an applied current. The first light emitting unit EU1 may include a first light emitting layer EML1, a first electron transport unit ETU1, and a first hole transport unit HTU1. The first light emitting layer EML1 may be located between the first electron transport unit ETU1 and the first hole transport unit HTU1. The second light emitting unit EU2 may include a second light emitting layer EML2, a second electron transport unit ETU2, and a second hole transport unit HTU2. The second light emitting layer EML2 may be located between the second electron transport unit ETU2 and the second hole transport unit HTU2. Each of the first and second hole transport units HTU1 and HTU2 may

include at least one of a hole injection layer HIL or a hole transport layer HTL. In addition, each of the first and second hole transport units HTU1 and HTU2 may further include a hole buffer layer, an electron blocking layer, and the like if necessary. The first and second hole transport units HTU1 and HTU2 may have configurations equal to each other or different from each other.

The first hole transport unit HTU1 may include a p-hole injection layer p-HIL in which a known hole injection material is doped with a p-type dopant. For example, the p-hole injection layer p-HIL may be located between the first to third anodes AE1, AE2, and AE3 and the hole transport layer HTL. This p-hole injection layer p-HTL may perform a function of smoothly injecting a hole transferred from each of the first to third anodes AE1, AE2, and AE3. The p-hole injection layer p-HIL may be separated for each sub-pixel, but may be formed integrally over the entire surface of the substrate SUB (refer to FIG. 6). However, in FIG. 7, the p-hole injection layer (p-HIL) is illustrated as a single layer within the hole injection layer (HIL), but the embodiments are not limited thereto. For example, the hole injection layer (HIL) may be a p-hole injection layer (p-HIL).

Each of the first and second electron transport units ETU1 and ETU2 may include at least one of an electron injection layer EIL or an electron transport layer ETL. In addition, each of the first and second electron transport units ETU1 and ETU2 may further include an electron buffer layer, a hole blocking layer, and the like if necessary. The first and second electron transport units ETU1 and ETU2 may have configurations equal to each other or different from each other.

A connection layer, which may be provided in a form of the charge generation layer CGL, may be located between the first light emitting unit EU1 and the second light emitting unit EU2 to connect the first light emitting unit EU1 and the second light emitting unit EU2 to each other. According to some embodiments, the charge generation layer CGL may include an n-type electron generation layer n-CGL for supplying a charge to the first light emitting unit EU1 and a p-type electron generation layer p-CGL for supplying a hole to the second light emitting unit EU2. For example, the n-type electron generation layer n-CGL may include an alkali metal, an alkaline earth metal, a lanthanide-based metal, or a combination thereof. The p-type charge generation layer p-CGL may include a p-type dopant such as HAT-CN, TCNQ, or NDP-9. However, embodiments are not limited thereto.

According to some embodiments, the first light emitting layer EML1 and the second light emitting layer EML2 may generate light of different colors. Light emitted from each of the first light emitting layer EML1 and the second light emitting layer EML2 may be mixed and viewed as white light. For example, the first light emitting layer EML1 may generate light of a blue color, and the second light emitting layer EML2 may generate light of a yellow color. According to some embodiments, the second light emitting layer EML2 may include a structure in which a first sub light emitting layer configured to generate light of a red color and a second sub light emitting layer configured to generate light of a green color are stacked. The light of the red color and the light of the green color may be mixed, and thus the light of the yellow color may be provided. In this case, an intermediate layer configured to perform a function of transporting holes and/or blocking transport of electrons may be further located between the first and second sub light emitting layers. According to some embodiments, the first light emitting layer EML1 and the second light emitting layer EML2 may generate light of the same color.

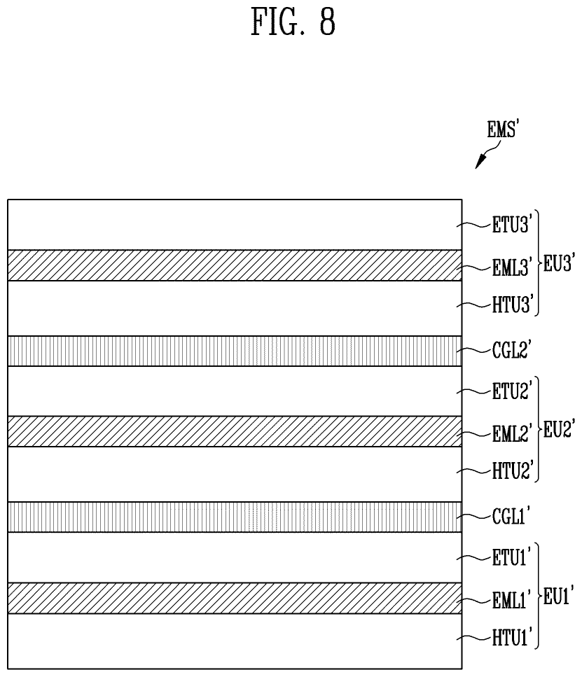

FIG. 8 is a cross-sectional view illustrating aspects of a light emitting structure included in any one of the first to third light emitting elements of FIG. 6 according to some embodiments.

Referring to FIG. 8, the light emitting structure EMS′ may have a tandem structure in which first to third light emitting units EU1′ to EU3′ are stacked. The light emitting structure EMS′ may be configured substantially equally in each of the first to third light emitting elements LD1 to LD3 of FIG. 7.

Each of the first to third light emitting units EU1′ to EU3′ may include a light emitting layer that generates light according to an applied current. The first light emitting unit EU1′ may include a first light emitting layer EML1′, a first electron transport unit ETU1′, and a first hole transport unit HTU1′. The first light emitting layer EML1′ may be located between the first electron transport unit ETU1′ and the first hole transport unit HTU1′. The second light emitting unit EU2′ may include a second light emitting layer EML2′, a second electron transport unit ETU2′, and a second hole transport unit HTU2′. The second light emitting layer EML2′ may be located between the second electron transport unit ETU2′ and the second hole transport unit HTU2′. The third light emitting unit EU3′ may include a third light emitting layer EML3′, a third electron transport unit ETU3′, and a third hole transport unit HTU3′. The third light emitting layer EML3′ may be located between the third electron transport unit ETU3′ and the third hole transport unit HTU3′.

Each of the first to third hole transport units HTU1′ to HTU3′ may include at least one of the hole injection layer HIL (refer to FIG. 7) or the hole transport layer HTL (refer to FIG. 7), and may further include a hole buffer layer, an electron blocking layer, and the like if necessary. The first to third hole transport units HTU1′ to HTU3′ may have configurations equal to each other or different from each other.

Each of the first to third electron transport units ETU1′ to ETU3′ may include at least one of the electron injection layer EIL (refer to FIG. 7) or the electron transport layer ETL (refer to FIG. 7), and may further include an electron buffer layer, a hole blocking layer, and the like, if necessary. The first to third electron transport units ETU1′ to ETU3′ may have configurations equal to each other or different from each other.

A first charge generation layer CGL1′ may be located between the first light emitting unit EU1′ and the second light emitting unit EU2′. A second charge generation layer CGL2′ may be located between the second light emitting unit EU2′ and the third light emitting unit EU3′.

According to some embodiments, the first to third light emitting layers EML1′ to EML3′ may generate light of different colors. Light emitted from each of the first to third light emitting layers EML1′ to EML3′ may be mixed and may be viewed as white light. For example, the first emitting layer EML1′ may generate light of a blue color, the second emitting layer EML2′ may generate light of a green color, and the third emitting layer EML3′ may generate light of a red color.

According to some embodiments, two or more of the first to third light emitting layers EML1′ to EML3′ may generate light of the same color.

Differently from that shown in FIGS. 7 and 8, the light emitting structure EMS of FIG. 6 may include one light emitting unit in each of the first to third light emitting elements LD1 to LD3. At this time, the light emitting unit included in each of the first to third light emitting elements LD1 to LD3 may be configured to emit light of different colors. For example, the light emitting unit of the first light emitting element LD1 may emit the light of the red color, the light emitting unit of the second light emitting element LD2 may emit the light of the green light, and the light emitting unit of the third light emitting element LD3 may emit the light of the blue color. In this case, differently from that shown in FIG. 6, the light emitting units of the first to third sub-pixels SP1 to SP3 may be separated from each other, and each of them may be located in the opening OP of the pixel defining layer PDL. In this case, at least a portion of the first to third color filters CF1 to CF3 may be omitted.

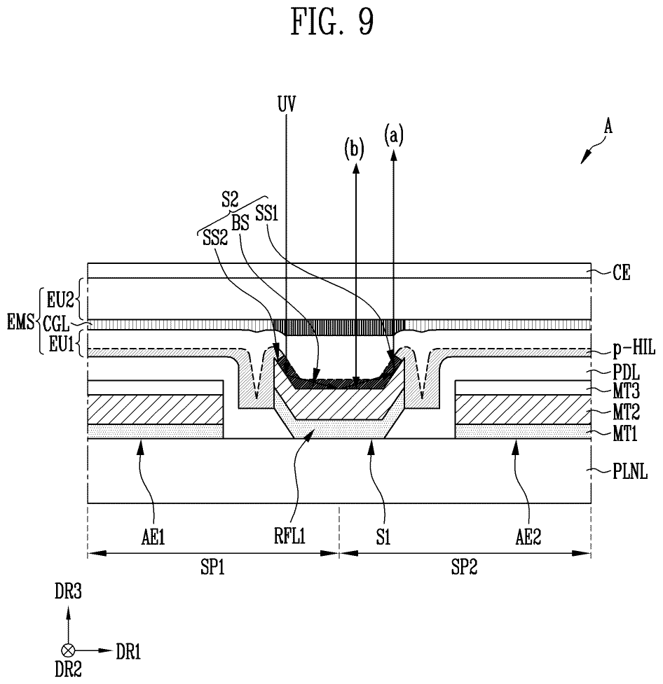

FIG. 9 is an enlarged view illustrating a portion A of FIG. 6.

Referring to FIG. 9, the first reflective layer RFL1 may be located under the light emitting structure EMS, and in particular, may be located in a center area of the pixel defining layer PDL. The first reflective layer RFL1 may be located between the first anode electrode AE1 of the first sub-pixel SP1 and the second anode electrode AE2 of the second sub-pixel SP2. Hereinafter, the first reflective layer RFL1 is described with reference to FIG. 9, but the second reflective layer RFL2 may also be described substantially equally to the first reflective layer RFL1. Hereinafter, an overlapping description is omitted.

The first reflective layer RFL1 may include a reflective material that reflects the ultraviolet rays UV. The first reflective layer RFL1 may include the same material as the first and second anode electrodes AE1 and AE2. According to some embodiments, each of the first and second anode electrodes AE1 and AE2 may include a first metal layer MT1, a second metal layer MT2, and a third metal layer MT3 sequentially stacked. For example, the first metal layer MT1 may be formed on the planarization layer PLNL and may include a reflective material such as titanium (Ti). The first metal layer MT1 may be formed on the second metal layer MT2 and may include a reflective material such as aluminum (Al) alloy. The third metal layer MT3 may be formed on the second metal layer MT2 and may include a material with a high work function, such as indium tin oxide (ITO). However, this is an example and a material forming the first to third metal layers MT1 to MT3 is not limited thereto.

The first reflective layer RFL1 may be formed on the planarization layer PLNL or the pixel defining layer PDL. The first reflective layer RFL1 may include at least one of the first metal layer MT1, the second metal layer MT2, or the third metal layer MT3. Referring to FIG. 9, the first reflective layer RFL1 may have a structure in which the first and second metal layers MT1 and MT2 are sequentially stacked. However, a structure of the first reflective layer RFL1 is not limited thereto. For example, the first reflective layer RFL1 may have a structure in which the first to third metal layers MT1 to MT3 are sequentially stacked. In addition, the first reflective layer RFL1 may have a single layer structure formed of the first metal layer MT1, the second metal layer MT2, or the third metal layer MT3.

The light emitting structure EMS located on the first reflection layer RFL1 may include the first and second light emitting units EU1 and EU2, and the charge generation layer CGL located between the first and second light emitting units EU1 and EU2. The ultraviolet rays UV may be irradiated to the light emitting structure EMS through the openings M_OP1 and M_OP2 (refer to FIG. 6) of the mask MSK (refer to FIG. 6). The charge generation layer CGL and the p-hole injection layer p-HIL in the light emitting structure EMS may be disconnected or denatured by the irradiated ultraviolet rays UV. In FIG. 9, the charge generation layer CGL and the p-hole injection layer p-HIL are disconnected or denatured, but embodiments according to th present disclosure are not limited thereto. For example, other layers included in the light emitting structure EMS may be disconnected or denatured by the irradiated ultraviolet UV rays. Alternatively, all of the plurality of layers included in the light emitting structure EMS may be disconnected or denatured by the irradiated ultraviolet rays UV.

The first reflective layer RFL1 may reflect the ultraviolet rays UV back to the light emitting structure EMS, thereby increasing exposure of the ultraviolet rays UV for the light emitting structure EMS. According to some embodiments, the first reflective layer RFL1 may have a lower surface S1 adjacent to the substrate SUB (refer to FIG. 6) and an upper surface S2 opposite to the lower surface S1. The upper surface S2 of the first reflective layer RFL1 may have a shape in which a center portion is recessed in a direction facing the substrate SUB or the lower surface S1. In addition, the lower surface S1 of the first reflective layer RFL1 may have a shape in which a center portion is recessed in the direction facing the substrate SUB. Due to the recessed shape of the first reflection layer RFL1, diffuse reflection of the ultraviolet rays UV may increase. For example, the ultraviolet rays UV irradiated through the openings M_OP1 and M_OP2 of the mask MSK may be reflected back to the light emitting structure EMS by the upper surface S2 of the first reflective layer RFL1.

According to some embodiments, the upper surface S2 of the first reflective layer RFL1 may include first and second inclined surfaces SS1 and SS2, and a base surface BS connecting the first and second inclined surfaces SS1 and SS2. The ultraviolet rays UV may proceed in the direction opposite to the third direction DR3 and reach the second inclined surface SS2. The ultraviolet rays UV reaching the second inclined surface SS2 may be reflected toward the base surface BS by the second inclined surface SS2, the ultraviolet rays UV reaching the base surface BS may be reflected toward the first inclined surface SS1 by the base surface BS, and the ultraviolet rays UV reaching the first inclined surface SS1 may be output in the third direction DR3 by the first inclined surface SS1 (a). In addition, the ultraviolet rays UV may proceed in the direction opposite to the third direction DR3 and reach the base surface BS. The ultraviolet rays UV reaching the base surface BS may be reflected in the third direction DR3 by the base surface BS (b).

As described above, due to the recessed shape of the first reflection layer RFL1, diffuse reflection of the ultraviolet rays UV may increase. Accordingly, the light emitting structure EMS may be exposed not only to the irradiated ultraviolet rays UV but also to the ultraviolet rays UV reflected by the first reflective layer RFL1. As described above, the first reflective layer RFL1 may increase a disconnection effect with a small amount of ultraviolet rays UV. In addition, the first reflective layer RFL1 may minimize an area to which the ultraviolet rays UV are irradiated.

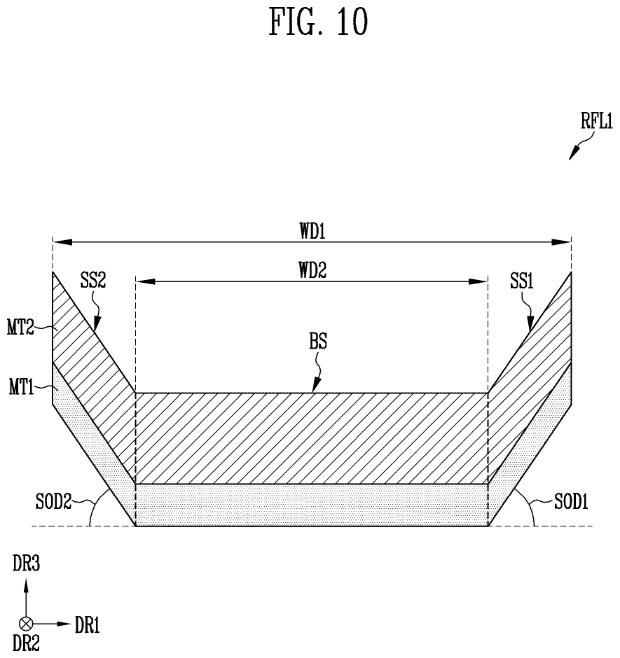

FIG. 10 is an enlarged view illustrating aspects of a reflective layer of FIG. 6 according to some embodiments.

Referring to FIG. 10, the first reflective layer RFL1 may include the base surface BS and the inclined surfaces SS1 and SS2 extending from the base surface BS. The base surface BS and the inclined surfaces SS1 and SS2 may have a structure in which the first and second metal layers MT1 and MT2 are stacked. In FIG. 10, the first reflective layer RFL1 includes the first and second metal layers MT1 and MT2 as an example, but the first reflective layer RFL1 may include the first to third metal layers MT1 to MT3. Hereinafter, the first reflective layer RFL1 is described with reference to FIG. 10, but this may be equally applied to the second reflective layer RFL2.

The first reflective layer RFL1 may include the base surface BS parallel to the substrate SUB (refer to FIG. 6). The first reflective layer RFL1 may include the first inclined surface SS1 extending in the first direction DR1 from the base surface BS. In addition, the first reflective layer RFL1 may include the second inclined surface SS2 extending in a direction opposite to the first direction DR1.

As the first reflective layer RFL1 includes the first and second inclined surfaces SS1 and SS2, the first reflective layer RFL1 may have a first width WD1, and the base surface BS may have a second width WD2 narrower than the first width WD1. For example, the first width WD1 may be 110 nm and the second width WD2 may be 38 nm. However, this is an example and a size of the first reflective layer RFL1 is not limited thereto.

The first inclined surface SS1 may be inclined at a first angle SOD1 with respect to the base surface BS. The second inclined surface SS2 may be inclined at a second angle SOD2 with respect to the base surface BS. The first angle SOD1 of the first inclined surface SS1 and the second angle SOD2 of the second inclined surface SS2 may be the same angle. For example, the first and second angles SOD1 and SOD2 may be 45 degrees or more.

When the first and second inclined surfaces SS1 and SS2 of the first reflective layer RFL1 are inclined with respect to the base surface BS, a probability that the ultraviolet rays UV are reflected in the third direction DR3 by the first reflective layer RFL1 and provided back to the light emitting structure EMS may increase. As the first reflective layer RFL1 includes the first and second inclined surfaces SS1 and SS2, the area of the first reflective layer RFL1 may be reduced and reflection efficiency of the first reflective layer RFL1 for the ultraviolet rays UV may increase.

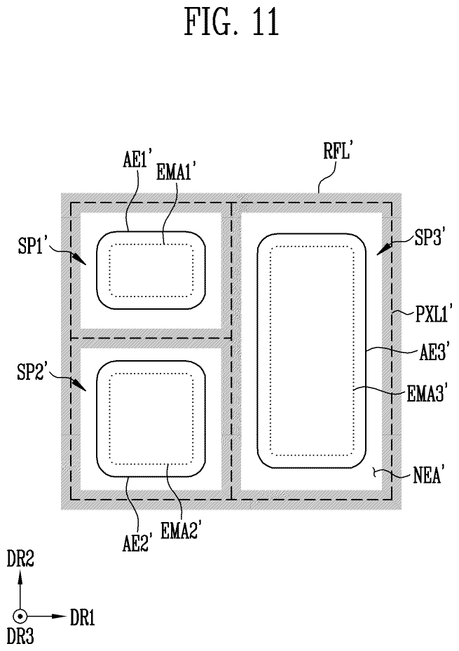

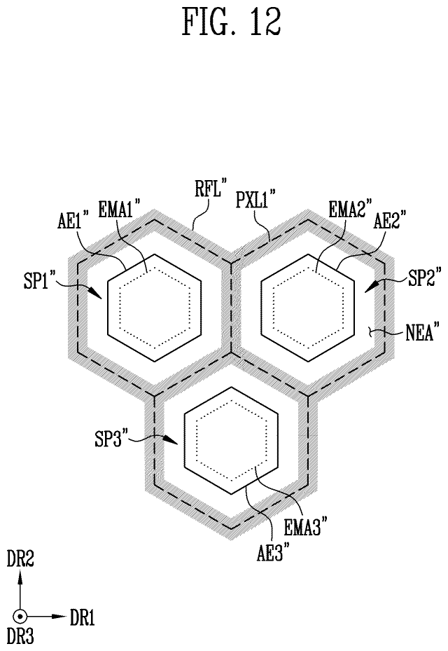

FIGS. 11 and 12 are plan views illustrating other embodiments of any of the pixels of FIG. 4.

Referring to FIG. 11, a first pixel PXL1′ may include first to third sub-pixels SP1′ to SP3′.

The first sub-pixel SP1′ may include a first anode electrode AE1′. The second sub-pixel SP2′ may include a second anode electrode AE2′. The third sub-pixel SP3′ may include a third anode electrode AE3′.

The first pixel PXL1′ may include a reflective layer RFL′ in the boundary area BDA (refer to FIG. 6) between the first to third sub-pixels SP1′ to SP3′. The reflective layer RFL′ may be arranged along a circumference of the first anode electrode AE1′ in the first sub-pixel SP1′. The reflective layer RFL′ may be arranged along a circumference of the second anode electrode AE2′ in the second sub-pixel SP2′. The reflective layer RFL′ may be arranged along a circumference of the third anode electrode AE3′ in the third sub-pixel SP3′. In addition, a portion of the reflective layer RFL′ may be located between the first anode electrode AE1′ and the second anode electrode AE2′. Another portion of the reflective layer RFL′ may be located between the second anode electrode AE2′ and the third anode electrode AE3′. Still another portion of the reflective layer RFL′ may be located between the first anode electrode AE1′ and the third anode electrode AE3′.

The first sub-pixel SP1′ may include a first emission area EMA1′ and a non-emission area NEA′ around the first emission area EMA1′. The first emission area EMA1′ may be positioned in the first anode electrode AE1′, and at least a portion may extend to the non-emission area NEA′. The second sub-pixel SP2′ may include a second emission area EMA2′ and a non-emission area NEA′ around the second emission area EMA2′. The second emission area EMA2′ may be positioned in the second anode electrode AE2′, and at least a portion may extend to the non-emission area NEA′. The third sub-pixel SP3′ may include a third emission area EMA3′ and a non-emission area NEA′ around the third emission area EMA3′. The third emission area EMA3′ may be positioned in the third anode electrode AE3′, and at least a portion may extend to the non-emission area NEA′.

The first sub-pixel SP1′ and the second sub-pixel SP2′ may be arranged in the second direction DR2. The third sub-pixel SP3′ may be arranged in the first direction DR1 with respect to each of the first and second sub-pixels SP1′ and SP2′.

The second sub-pixel SP2′ may have an area greater than that of the first sub-pixel SP1′, and the third sub-pixel SP3′ may have an area greater than that of the second sub-pixel SP2′. Accordingly, the second anode electrode AE2′ and the second emission area EMA2′ may have an area greater than that of the first anode electrode AE1′ and the first emission area EMA1′. The third anode electrode AE3′ and the third emission area EMA3′ may have an area greater than that of the second anode electrode AE2′ and the second emission area EMA2′. However, embodiments are not limited thereto. For example, the first and second sub-pixels SP1′ and SP2′ may have substantially the same area, and the third sub-pixel SP3′ may have an area greater than that of each of the first and second sub-pixels SP1′ and SP2′. As described above, the areas of the first to third sub-pixels SP1′ to SP3′ may be variously modified according to some embodiments.

Referring to FIG. 12, a first pixel PXL1″ may include a reflective layer RFL″ in the boundary area BDA (refer to FIG. 6) between first to third sub-pixels SP1″ to SP3″. The reflective layer RFL″ may be arranged along a circumference of a first anode electrode AE1″ in the first sub-pixel SP1″. The reflective layer RFL″ may be arranged along a circumference of a second anode electrode AE2″ in the second sub-pixel SP2″. The reflective layer RFL″ may be arranged along a circumference of the third anode electrode AE3″ in the third sub-pixel SP3″. In addition, a portion of the reflective layer RFL″ may be located between the first anode electrode AE1″ and the second anode electrode AE2″. Another portion of the reflective layer RFL″ may be located between the second anode electrode AE2″ and the third anode electrode AE3″. Still another portion of the reflective layer RFL″ may be located between the first anode electrode AE1″ and the third anode electrode AE3″.

The first sub-pixel SP1″ may include a first emission area EMA1″ and a non-emission area NEA″ around the first emission area EMA1″. The first emission area EMA1″ may be positioned in the first anode electrode AE1″, and at least a portion may extend to the non-emission area NEA″. The second sub-pixel SP2″ may include a second emission area EMA2″ and a non-emission area NEA″ around the second emission area EMA2″. The second emission area EMA2″ may be positioned in the second anode electrode AE2″, and at least a portion may extend to the non-emission area NEA′. The third sub-pixel SP3″ may include a third emission area EMA3″ and a non-emission area NEA″ around the third emission area EMA3″. The third emission area EMA3″ may be positioned in the first anode electrode AE3″, and at least a portion may extend to the non-emission area NEA″.

The first to third sub-pixels SP1″ to SP3″ may have polygonal shapes when viewed in the third direction DR3. For example, the first to third sub-pixels SP1″ to SP3″ may have hexagonal shapes as shown in FIG. 12.

The first to third anode electrodes AE1″ to AE3″ may have polygonal shapes when viewed in the third direction DR3. However, embodiments are not limited thereto. For example, each of the first to third emission areas AE1″ to AE3″ may have a circular shape.

The first to third emission areas EMA1″ to EMA3″ may have polygonal shapes when viewed in the third direction DR3. However, embodiments are not limited thereto. For example, each of the first to third emission areas EMA1″ to EMA3″ may have a circular shape.

The first and third sub-pixels SP1″ and SP3″ may be arranged in the first direction DR1. The second sub-pixel SP2″ may be arranged in a direction inclined (or in a diagonal direction) at an acute angle with respect to the second direction DR2 with respect to the first sub-pixel SP1″.

An arrangement of sub-pixels shown in FIGS. 5, 11, and 12 is illustrated, and embodiments according to the present disclosure are not limited thereto. Each pixel may include two or more sub-pixels, and the sub-pixels may be arranged in various methods. Each of the sub-pixels may have various shapes, and each of anode electrodes and emission areas thereof may also have various shapes.

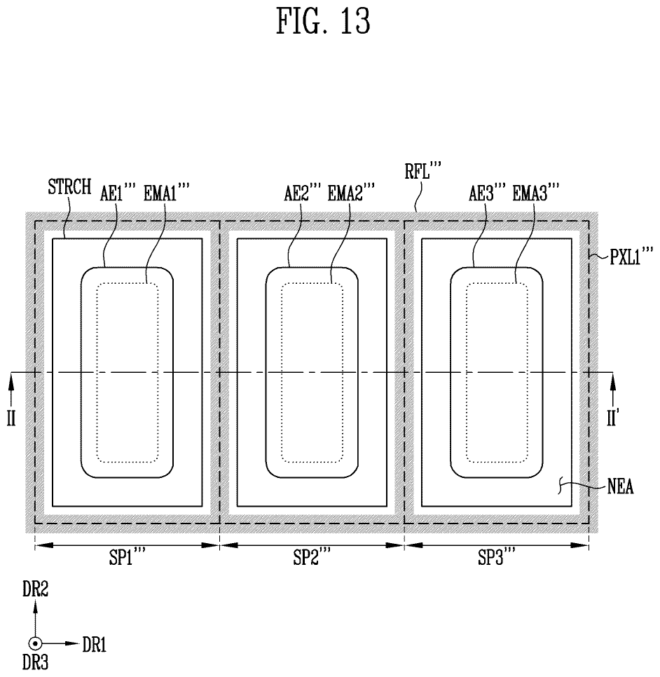

FIG. 13 is a plan view illustrating aspects of a pixel of FIG. 4 according to some embodiments. Referring to FIG. 13, a first pixel PXL1′″ may include first to third sub-pixels SP1′″ to SP3′″. Hereinafter, the first to third sub-pixels SP1′″ to SP3′″, first to third anode electrodes AE1′″ to AE3′″, and first to third emission areas EMA1′″ to EMA3′″ may be described similarly to the above-described FIGS. 5, 11, and 12. An overlapping description thereof is omitted.

The first sub-pixel SP1′″ may include a first anode electrode AE1′″. The second sub-pixel SP2′″ may include a second anode electrode AE2′″. The third sub-pixel SP3′″ may include a third anode electrode AE3′″.

The first pixel PXL1′″ may include a reflective layer RFL′″ and a sub-trench STRCH in the boundary area BDA (refer to FIG. 6) between the first to third sub-pixels SP1′″ to SP3′″. In particular, the sub-trench STRCH may be an area further recessed from a recessed shape where the reflective layer RFL′″ is located.

The sub-trench STRCH may be arranged along a circumference of the first anode electrode AE1′″ in the first sub-pixel SP1′″. The sub-trench STRCH may be arranged along a circumference of the second anode electrode AE2″ in the second sub-pixel SP2′″. The sub-trench STRCH may be arranged along a circumference of the third anode electrode AE3′″ in the third sub-pixel SP3′″.

The sub-trench STRCH may be located between the first anode electrode AE1′″ and the reflective layer RFL′″. In addition, a portion of the sub-trench STRCH may be located between the first anode electrode AE1′″ and the second anode electrode AE2′″. The sub-trench STRCH may be located between the second anode electrode AE2′″ and the reflective layer RFL′″. In addition, another portion of the sub-trench STRCH may be located between the second anode electrode AE2′″ and the third anode electrode AE3′″. The sub-trench STRCH may be located between the third anode electrode AE3′″ and the reflective layer RFL′″.

As described above, as the sub-trench STRCH is provided, a probability that at least a portion of the layers of the light emitting structure EMS have a discontinuous portion in the boundary area BDA may be further increased. Accordingly, at least a portion of the layers of the light emitting structure EMS may be disconnected with higher reliability in the boundary area BDA.

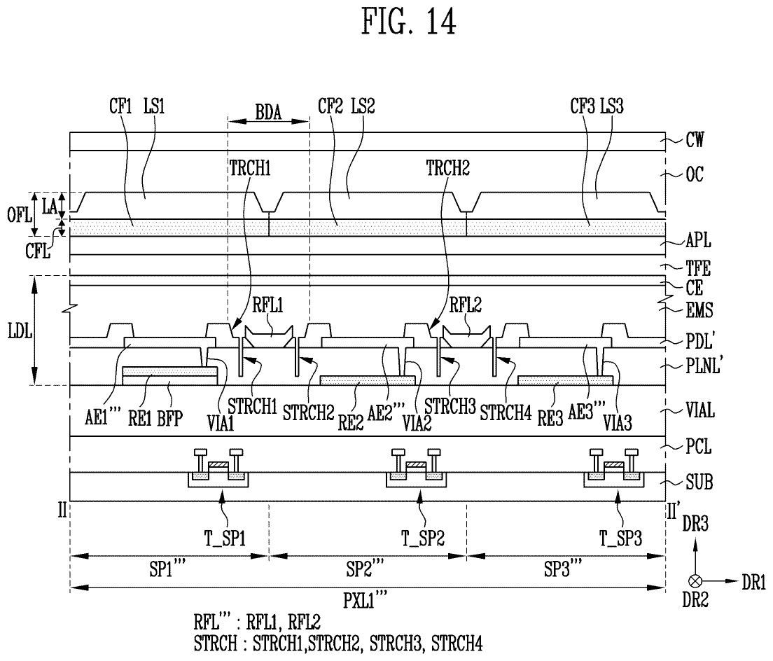

FIG. 14 is a cross-sectional view taken along a line II˜II′ of FIG. 13. Referring to FIG. 14, the substrate SUB, the pixel circuit layer PCL, the transistor T_SP1 of the first sub-pixel SP1′″, the transistor T_SP2 of the second sub-pixel SP2′″, the transistor T_SP3 of the third sub-pixel SP3′″, the via layer VIAL, a planarization layer PLNL′, the first to third reflective electrodes RE1 to RE3, the buffer pattern BFP, a pixel defining layer PDL′, the anode electrodes AE1 to AE3, the first and second reflective layers RFL1 and RFL2, the light emitting structure EMS, the cathode electrode CE, a light emitting element layer LDL′, the encapsulation layer TFE, the adhesive layer APL, the optical functional layer OFL, the color filter layer CFL, the first to third color filters CF1 to CF3, the first to third lenses LS1 to LS3, the lens array LA, the overcoat layer OC, and the cover window CW may be provided.

The substrate SUB, the pixel circuit layer PCL, the transistor T_SP1 of the first sub-pixel SP1′″, the transistor T_SP2 of the second sub-pixel SP2′″, the transistor T_SP3 of the third sub-pixel SP3′″, the via layer VIAL, the first to third reflective electrodes RE1 to RE3, the buffer pattern BFP, the anode electrodes AE1 to AE3, the first and second reflective layers RFL1 and RFL2, the light emitting structure EMS, the cathode electrode CE, the encapsulation layer TFE, the adhesive layer APL, the optical functional layer OFL, the color filter layer CFL, the first to third color filters CF1 to CF3, the first to third lenses LS1 to LS3, the lens array LA, the overcoat layer OC, and the cover window CW may be described similarly to the embodiments of FIG. 6. Some overlapping description in relation to the embodiments of FIG. 6 may be omitted, and a point different from the embodiments described above is mainly described.

The pixel defining layer PDL′ may have a recessed shape in the boundary area BDA between the first sub-pixel SP1′″ and the second sub-pixel SP2′″.

Hereinafter, the recessed shape in FIG. 14 is described using a trench as an example, but the recessed shape is not limited to the trench.

The pixel defining layer PDL′ may include one or more sub-trenches STRCH further recessed from the first trench TRCH1. According to some embodiments, the pixel defining layer PDL′ may include a first sub-trench STRCH1 located between the first anode electrode AE1 and the first reflective layer RFL1. The pixel defining layer PDL′ may include a second sub-trench STRCH2 located between the second anode electrode AE2 and the first reflective layer RFL1. That is, the first and second sub-trenches STRCH1 and STRCH2 may be arranged to be spaced apart from each other with the first reflective layer RFL1 interposed therebetween. The first and second sub-trenches STRCH1 and STRCH2 may have a structure recessed from an upper surface of the pixel defining layer PDL′ to an inside of the planarization layer PLNL′.

The pixel defining layer PDL′ may include one or more sub-trenches STRCH further recessed from the second trench TRCH2 in the boundary area between the second sub-pixel SP2′″ and the third sub-pixel SP3′″. According to some embodiments, the pixel defining layer PDL′ may include a third sub-trench STRCH3 located between the second anode electrode AE2 and the second reflective layer RFL2. The pixel defining layer PDL′ may include a fourth sub-trench STRCH4 located between the third anode electrode AE3 and the second reflective layer RFL2. That is, the third and fourth sub-trenches STRCH3 and STRCH4 may be arranged to be spaced apart from each other with the second reflective layer RFL2 interposed therebetween. The third and fourth sub-trenches STRCH3 and STRCH4 may have a structure recessed from the upper surface of the pixel defining layer PDL′ to the inside of the planarization layer PLNL′.

By additionally forming the first to fourth sub-trenches STRCH1 to STRCH4 around the first and second reflective layers RFL1 and RFL2, a probability that at least a portion of the layers of the light emitting structure EMS has a discontinuous portion in the boundary area BDA may be further increased.

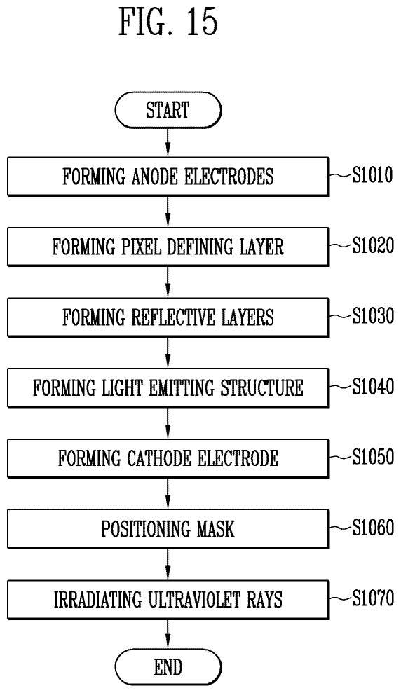

FIG. 15 is a flowchart illustrating aspects of a method of manufacturing a display device according to some embodiments. Although various operations are illustrated in FIG. 15, embodiments according to the present disclosure are not limited thereto. For example, according to some embodiments, the method of manufacturing a display device may include additional operations or fewer operations, or the order of operations may vary (unless otherwise stated or implied), without departing from the spirit and scope of embodiments according to the present disclosure.

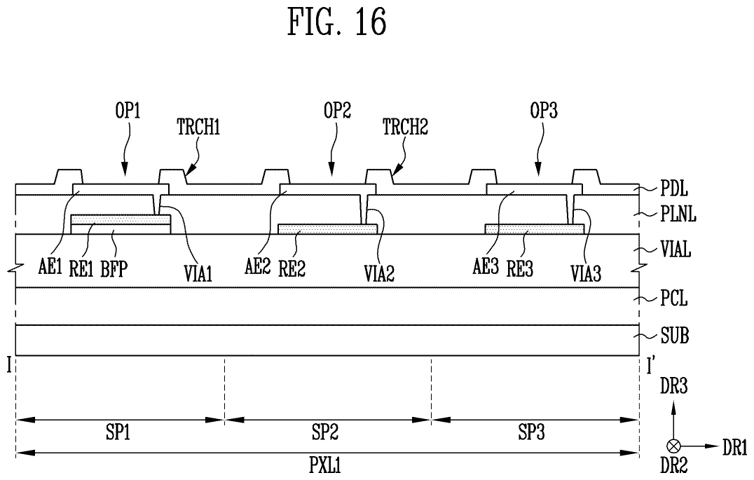

FIGS. 16 to 19 are cross-sectional views schematically illustrating a method of manufacturing a display device according to some embodiments. A detailed description of a method of manufacturing the display device 100 (refer to FIG. 1) of FIG. 15 may be described similarly to the embodiments of FIGS. 1 to 14.

Referring to FIG. 15, a method of manufacturing the display device 100 according to embodiments of the disclosure may include forming anode electrodes (S1010), forming a pixel defining layer (S1020), forming reflective layers (S1030), forming a light emitting structure (S1040), forming a cathode electrode (S1050), positioning a mask (S1060), and irradiating ultraviolet rays (S1070).

The pixel circuit layer PCL, the via layer VIAL, and the planarization layer PLNL may be sequentially stacked and formed on the substrate SUB.

Referring to FIGS. 15 and 16, in S1010, the first to third anode electrodes AE1 to AE3 may be formed on the planarization layer PLNL to be spaced apart from each other in the first direction DR1.

In S1020, the pixel defining layer PDL may be located on portions of the first to third anode electrodes AE1 to AE3 and the planarization layer PLNL. The pixel defining layer PDL may include openings OP1 to OP3 exposing a portion of each of the first to third anode electrodes AE1 to AE3. The pixel defining layer PDL may include first and second trenches TRCH1 and TRCH2 arranged to surround the first to third anode electrodes AE1 to AE3.

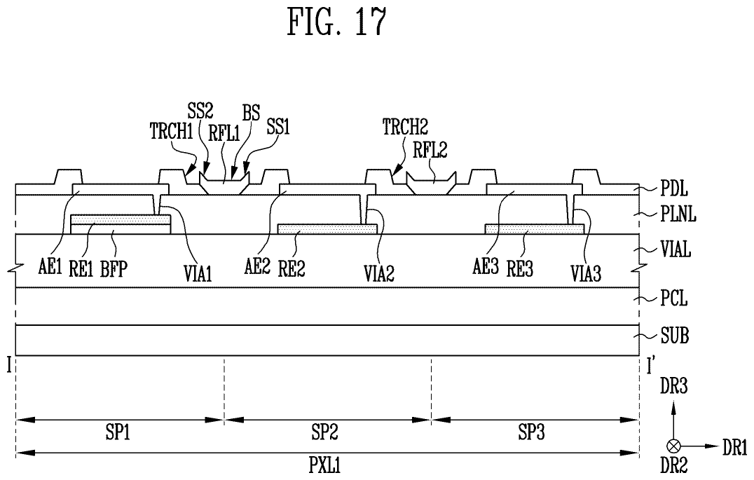

Referring to FIGS. 15 and 17, in S1030, the first and second reflective layers RFL1 and RFL2 may be formed in or on the pixel defining layer PDL. According to some embodiments, the first and second reflective layers RFL1 and RFL2 may be formed on the pixel defining layer PDL through exposure, development, etching processes, and the like. The first and second reflective layers RFL1 and RFL2 may be formed to overlap the first and second trenches TRCH1 and TRCH2, respectively. The first reflective layer RFL1 may be located between the first anode electrode AE1 of the first sub-pixel SP1 and the second anode electrode AE2 of the second sub-pixel SP2. The second reflective layer RFL2 may be located between the second anode electrode AE2 of the second sub-pixel SP2 and the third anode electrode AE3 of the third sub-pixel SP3.

The first and second reflective layers RFL1 and RFL2 may include a reflective material that reflects the ultraviolet rays UV. The first and second reflective layers RFL1 and RFL2 may include the same material as the first and second anode electrodes AE1 and AE2. In addition, each of the first and second reflective layers RFL1 and RFL2 may have a shape in which a central portion is recessed in the direction opposite to the third direction DR3 facing the substrate SUB. The recessed shape of the first and second reflective layers RFL1 and RFL2 may increase diffuse reflection of the ultraviolet rays UV. As described above with reference to FIG. 10, the first and second reflective layers RFL1 and RFL2 may be formed to include the base surface BS parallel to the substrate SUB and the first and second inclined surfaces SS1 and SS2 extending from the base surface BS. Here, each of the first and second inclined surfaces SS1 and SS2 may have a shape inclined at an angle (e.g., a set or predetermined angle) with respect to the base surface BS.

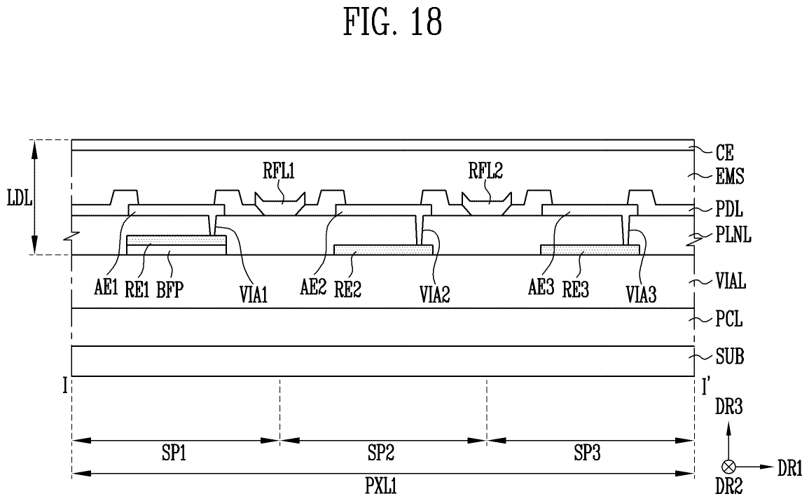

Referring to FIGS. 15 and 18, in S1040, the light emitting structure EMS including a plurality of light generation layers may be formed on the first to third anode electrodes AE1 to AE3 and the pixel defining layer PDL.

The light emitting structure EMS may include a low-molecular or high-molecular organic material. The light emitting structure EMS may be formed in vapor deposition, printing, slit coating techniques, but is not limited thereto. The light emitting structure EMS may be formed on a portion of the first to third anode electrodes AE1 to AE3 and the pixel defining layer PDL. The light emitting structure EMS may also be formed on the first and second reflective layers RFL1 and RFL2.

Referring to FIGS. 15 and 18, in S1050, the cathode electrode CE may be formed on the light emitting structure EMS. The cathode electrode CE may be a common electrode commonly formed in the first to third sub-pixels SPX1 to SPX3.

On the cathode electrode CE, the encapsulation layer TFE, the adhesive layer APL, the optical function layer OFL, the color filter layer CFL, the first to third color filters CF1 to CF3, the first to third lenses LS1 to LS3, the lens array LA, the overcoat layer OC, and the cover window CW may be provided.

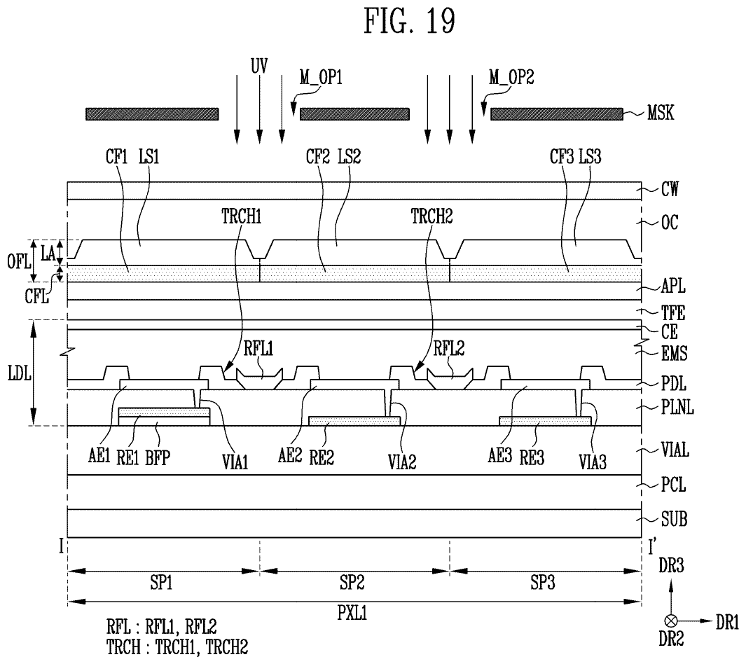

Referring to FIGS. 15 and 19, in S1060, the mask MSK having the first and second openings M_OP1 and M_OP2 may be positioned on the cover window CW. The mask MSK may be positioned so that the first and second openings M_OP1 and M_OP2 overlap the first and second trenches TRCH1 and TRCH2 between the first to third anode electrodes AE1 to AE3. In particular, the mask MSK may be positioned so that the first and second openings M_OP1 and M_OP2 overlap the first and second reflective layers RFL1 and RFL2.

Referring to FIGS. 15 and 19, in S1060, the ultraviolet rays UV may be irradiated through the first and second openings M_OP1 and M_OP2 of the mask MSK. The ultraviolet rays UV may be irradiated to the light emitting structure EMS through the first and second openings M_OP1 and M_OP2 of the mask MSK. In addition, the ultraviolet rays UV may be reflected back to the light emitting structure EMS by the first and second reflective layers RFL1 and RFL2. The light emitting structure EMS may be exposed not only to the irradiated ultraviolet rays UV but also to the ultraviolet rays UV reflected by the first and second reflective layers RFL1 and RFL2. Therefore, at least a portion of the layers in the light emitting structure EMS may be disconnected or bent on the first and second reflective layers RFL1 and RFL2 by a small amount of ultraviolet rays UV. For example, the disconnected layers in the light emitting structure EMS may be the charge generation layer CGL and the p-hole injection layer p-HIL.

In the display device and the method of manufacturing the same according to embodiments of the disclosure, by arranged (or forming) the reflective layer to surround each of the anode electrodes, at least a portion of the layers configuring the light emitting structure may be effectively disconnected by the ultraviolet rays UV. Accordingly, a lateral leakage phenomenon caused by common provision of the light emitting structure in the sub-pixels may be effectively improved.

According to embodiments of the disclosure, a display device with relatively improved reliability and a method of manufacturing the same are provided.

An effect according to embodiments is not limited to the content described above, and further various effects are included in the present specification.

Although specific embodiments and application examples are described herein, other embodiments and modifications may be derived from the above description. Therefore, the spirit of the disclosure is not limited to such embodiments, and extends to the scope of the claims set forth below, and their equivalents.

What is claimed is:

1. A display device comprising:
a substrate;
a pixel circuit layer on the substrate;
anode electrodes on the pixel circuit layer;
a pixel defining layer on a portion of the anode electrodes and the pixel circuit layer, and having a recessed shape in a direction of the substrate between the anode electrodes, wherein the recessed shape is arranged along a circumference of each of the anode electrodes;
a light emitting structure on the anode electrodes and the pixel defining layer and including a plurality of light generation layers;
a cathode electrode on the light emitting structure; and
a reflective layer overlapping the recessed shape and located between the light emitting structure and the pixel circuit layer.

2. The display device according to claim 1, wherein the reflective layer is arranged along the circumference of each of the anode electrodes.

3. The display device according to claim 1, wherein the reflective layer includes a same material as the anode electrodes.

4. The display device according to claim 1, wherein a sub-trench further recessed from the recessed shape is between one of the anode electrodes and the reflective layer, and
the sub-trench is arranged along a circumference of the one of the anode electrodes.

5. The display device according to claim 1, wherein a first sub-trench further recessed from the recessed shape between one of the anode electrodes and the reflective layer, and a second sub-trench further recessed from the recessed shape between another of the anode electrodes and the reflective layer are arranged.

6. The display device according to claim 1, wherein the light emitting structure includes at least two light emitting units sequentially stacked and at least one charge generation layer between the light emitting units,
each of the at least two light emitting units includes a light emitting layer, and
the at least one charge generation layer is disconnected in an area overlapping the recessed shape.

7. The display device according to claim 1, wherein the reflective layer has a lower surface adjacent to the substrate and an upper surface opposite to the lower surface, and
the upper surface of the reflective layer has a recessed shape in a direction facing the substrate.

8. The display device according to claim 7, wherein the lower surface of the reflective layer has a recessed shape in the direction facing the substrate.

9. The display device according to claim 1, wherein the reflective layer includes a base surface parallel to the substrate and inclined surfaces extending from the base surface, and
each of the inclined surfaces is inclined at a predetermined angle with respect to the base surface.

10. The display device according to claim 9, wherein each of the inclined surfaces has an angle of 45 degrees or more with respect to the base surface.

11. The display device according to claim 9, wherein the reflective layer has a first width, and the base surface has a second width narrower than the first width.

12. The display device according to claim 1, wherein an anode electrode from among the anode electrodes has a quadrangular shape or a hexagonal shape in a plan view.

13. A method of manufacturing a display device, the method comprising:
forming anode electrodes on a substrate;
forming a pixel defining layer on a portion of the anode electrodes and a pixel circuit layer, wherein the pixel defining layer forms a recessed shape in a direction of the substrate between the anode electrodes along a circumference of each of the anode electrodes;
forming a reflective layer overlapping the recessed shape;
forming a light emitting structure including a plurality of light generation layers on the anode electrodes and the pixel defining layer; and
forming a cathode electrode on the light emitting structure,
wherein the reflective layer is between the light emitting structure and the pixel circuit layer.

14. The method according to claim 13, further comprising:
positioning a mask having an opening overlapping the reflective layer on the cathode electrode; and
irradiating ultraviolet rays through the opening.

15. The method according to claim 13, wherein the reflective layer is arranged along the circumference of each of the anode electrodes.

16. The method according to claim 13, wherein the reflection layer includes a same material as the anode electrodes.

17. The method according to claim 13, wherein the reflective layer has a lower surface adjacent to the substrate and an upper surface opposite to the lower surface, and
the upper surface of the reflective layer has a recessed shape in a direction facing the substrate.

18. The method according to claim 13, wherein the reflective layer includes a base surface parallel to the substrate and inclined surfaces extending from the base surface, and
each of the inclined surfaces is inclined at a predetermined angle with respect to the base surface.
